(19) United States
(12) Patent Application Publication
(10) Pub. No.: US 2026/0081054 A1
(43) Pub. Date: Mar. 19, 2026

(54) SMART CONSTRUCTION BOARD

(71) Applicant: Re:Build Manufacturing, LLC, Framingham, MA (US)

(72) Inventor: Andrew James Armstrong, Oxford (GB)

(73) Assignee: Re:Build Manufacturing, LLC, Framingham, MA (US)

(21) Appl. No.: 19/328,462

(22) Filed: Sep. 15, 2025

Related U.S. Application Data
(60) Provisional application No. 63/694,461, filed on Sep. 13, 2024.

(51) Int. Cl. H01B 13/012; G01R 31/58; G06F 30/27; H01B 7/00

(52) U.S. Cl. CPC H01B 13/01227; G01R 31/58; G06F 30/27; H01B 13/01209; H01B 7/0045

(57) ABSTRACT

A smart construction board may be provided that uses first and second dynamic display devices, respectively having first and second surfaces configured to display first and second portions of a schematic; a computing device, comprising a processor and a memory including instructions that when executed by the processor perform operations that include: identifying a first physical position of the first dynamic display device in a physical environment; identifying a second physical position of the second dynamic display device in the physical environment; and selecting the first portion from the schematic based on sizes of the first dynamic display device and the second dynamic display device and a first correlation of the first physical position to a first schematic position in the schematic and a second correlation of the second physical position to a second schematic position in the schematic.

### CROSS-REFERENCES TO RELATED DISCLOSURES

The present disclosure claims priority to U.S. Provisional Patent Application No. 63/694,461, titled “SMART CONSTRUCTION BOARD” and filed on 2024 Sep. 13, which is incorporated by reference in its entirety.

### BACKGROUND

When manufacturing complicated articles, various techniques may be used to ensure that the article meets design specifications. These techniques can include poka-yoke designs where some or all possibilities for mis-assembly have been engineered out of the fabrication process, providing human fabricators with training and detailed instructions (e.g., via formboards), replacing human fabricators with robots, mid-build and post-build testing, and combinations thereof. However, each of these existing solutions generally require significant design and material inputs, with varying levels of scrap or re-work, rendering the fabrication process for such articles rigid and discouraging improved designs or fabrication techniques.

### SUMMARY

The present disclosure provides for various systems, methods, and techniques related to a smart construction board, which allows designers to rapidly adapt for the construction of new articles of manufacture with existing manufacturing hardware.

Additional features and advantages of the disclosed method and apparatus are described in, and will be apparent from, the following Detailed Description and the Figures. The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the inventive subject matter.

### BRIEF DESCRIPTION OF THE DRAWINGS

FIG. 1 illustrates an example build environment for fabricating a wire harness, according to embodiments of the present disclosure.

FIGS. 2A-2K illustrate various example display mounts for the fixtures used in conjunction with the display devices, according to embodiments of the present disclosure.

FIG. 3 illustrates various example heads for the fixtures used in conjunction with the display devices, according to embodiments of the present disclosure.

FIGS. 4A-4D illustrate various examples of reconfigurable multi-display handling for a fabrication system, according to embodiments of the present disclosure.

FIGS. 5A-5E illustrate an example image of a wire harness to be constructed as modified for sequential display over a plurality of dynamic displays, according to embodiments of the present disclosure.

FIG. 6 is a flowchart for an example method of operating reconfigurable multi-display setups for a fabrication system, according to embodiments of the present disclosure.

FIG. 7 illustrates networks within an example wire harness under test, according to embodiments of the present disclosure.

FIGS. 8A-8B are flowcharts of an example methods of testing a wire harness, according to embodiment of the present disclosure.

FIG. 9 illustrates an example computing environment in which AI modules are deployed to aid in wire harness design, manufacture, and test, according to embodiments of the present disclosure.

FIG. 10 illustrates a computing device, according to embodiments of the present disclosure.

FIG. 11 illustrates an example display device and sections thereof, according to embodiments of the present disclosure.

FIGS. 12A-12E illustrate example display device positioning systems, according to embodiments of the present disclosure.

FIGS. 13A-13E, 14A-14C, 15A-15C, and 16A-16D illustrate example use cases of dynamic displays, according to embodiments of the present disclosure.

FIG. 17 is a flowchart for an example method of configuring the display of a schematic during fabrication of an article of manufacture, according to embodiments of the present disclosure.

FIG. 18A-18K are example layouts of multiple display screens during fabrication of an article of manufacture, according to embodiments of the present disclosure.

### DETAILED DESCRIPTION

The present disclosure provides for various systems, methods, and techniques related to a smart construction board, which allows designers to rapidly adapt for the construction of new articles of manufacture with existing manufacturing hardware.

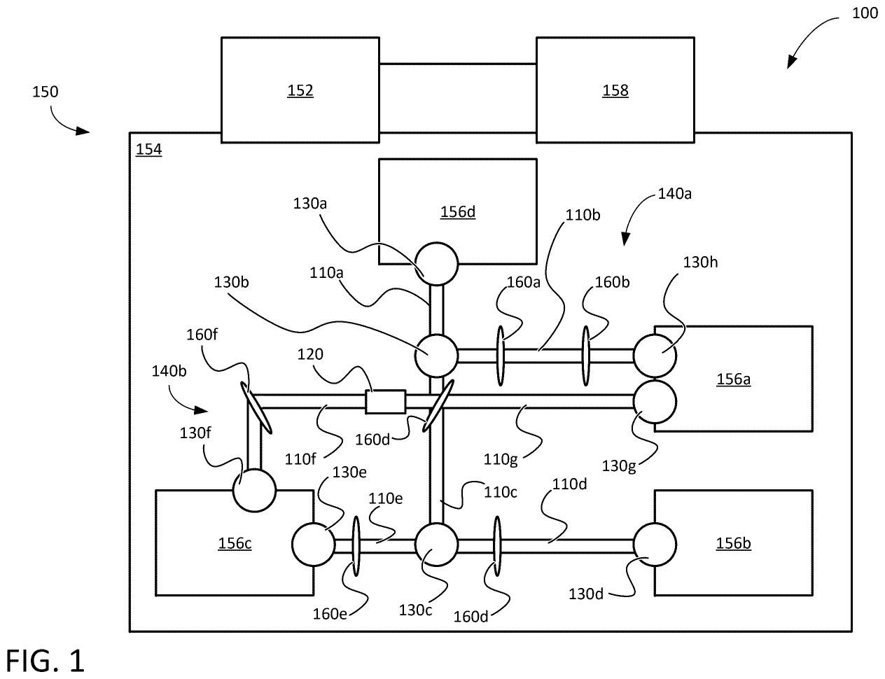

FIG. 1 illustrates an example build environment for fabricating a wire harness 100, according to embodiments of the present disclosure. A wire harness 100 is one example of an article of manufacture that may benefit from the techniques discussed herein related to agile manufacturing. Although generally discussed with respect to fabricating wire harnesses 100, the build environment described herein may be used in “dry runs” (e.g., to display fabrication instructions without actually fabricating the wire harness 100), for fabricating sub-assemblies of a wire harness 100 (e.g., fabricating some of a wire harness 100 indicated in a set of instructions), or to fabricate cables with one or more terminations, and other articles of manufacture.

A wire harness 100 is an article of manufacture that includes various cables 110a-g (generally or collectively, cables 110), splices 120 between cables 110, and connectors 130a-h (generally or collectively connectors 130) that are configured to connect two or more cables 110 or external devices (e.g., as terminals for the cables 110) in a defined pattern and form factor. Generally, the wire harness 100 may be subdivided into various networks 140a-b (generally or collectively, networks 140) of components that are (nominally) in communication (e.g., electrically, optically, pneumatically, hydraulically, etc. connected via the associated cables 110) with one another, and not in communication with components of another network 140. The present disclosure contemplates that more or fewer cables 110, splices 120, and connectors 130 grouped into more or fewer networks 140 with various topologies in addition to those shown in the example provided in FIG. 1 may be used in a wire harness 100; indeed, complicated wire harnesses 100 may include upwards of hundreds of various networks 140 defined among the various components.

As described herein, the cables 110 may include one or more electrically conductive wires (e.g., in single strand, coaxial, braided, etc. arrangements), electrical and thermal insulators, and various circuit elements (e.g., resistors, capacitors, inductors, diodes) to impart particular conducting characteristics to the cables 110. Additionally, in some embodiments, the cables 110 may include one or more optically transmissive fibers (e.g., fiber optic bundles), optical and thermal insulators, and optical control elements (e.g., reflectors, wavelength filters, tunnels) to impart particular optical transmission characteristics. In some embodiments, the cables 110 may include a combination of optical and electrical conductors and associated signal conditioning elements. In various embodiments, the cables 110 may terminate with various arrangements according to different commonly available formats and hardware to securely fasten to a connector 130. The terminations of the cables 110 may include various external terminals or structural elements that ensure a strong connection with a mating feature in a connector 130 (e.g., stripping away protective or insulative layers, arranging in a male-end housing configured for a female-end housing defined in a connector 130).

In some embodiments, the cables 110 may include one or more of tubes, pipes, hoses, or ducts configured for the transmission of fluids (e.g., hydraulic fluids, air, bodily fluids, therapeutic agents), and may include various sensors or control interfaces (e.g., electrical wires or optical fibers) embedded therein.

As described herein, the splices 120 refer to a joint formed between two or more cables 110 at a transmission boundary thereof (e.g., wire ends). In various embodiments, the splice 120 may include a sheath or covering (e.g., shrink tubing) placed around the joint after being formed, or may be left exposed. In various embodiments, the splice 120 is formed through mechanical joinery (e.g., braiding, butting, wrapping, crimping, etc.) or through chemical/thermal joinery (e.g., a weld).

As described herein, the connectors 130 refer a housing and the various electrical or optical circuits contained therein to connect the cables 110 to one another or to external devices. The connectors 130 may include various integrated circuits that include processors or application specific controls or circuitry to format the signals carried by the cables 110 (e.g., repeating, modulating, amplifying, digitizing, etc.), convert between optical signals and electrical signals, and translate between cables 110 of different gauges or resistances. The connectors 130 may include one or more cavities that are configured to accept the cables 110 into predefined arrangements. In some embodiments, an individual connector 130 may connect two or more cables 110, or two or more connectors 130 may connect to each other (and associated cables 110) to form a junction and establish a communications pathway among the associated cables 110. In some embodiments, the connector 130 may be an end terminal that may remain unconnected to any other cable 110 or other connectors 130, or is added temporarily (e.g., to hold wires/fibers in place for applying a splice 120).

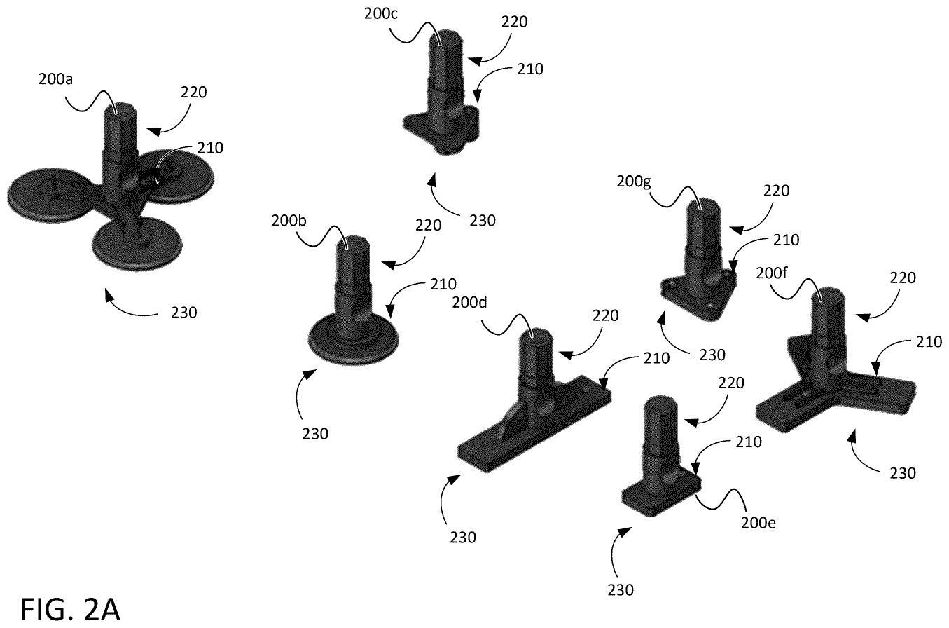

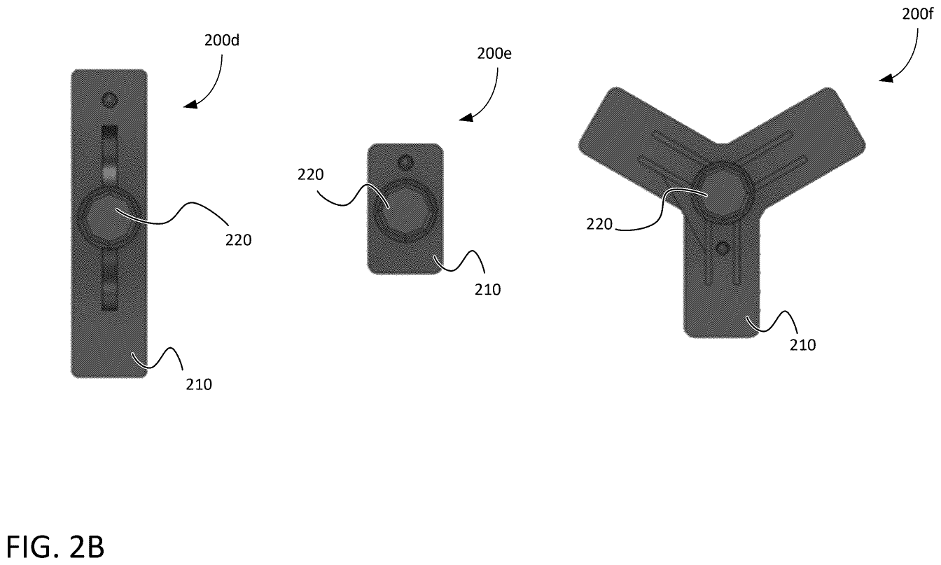

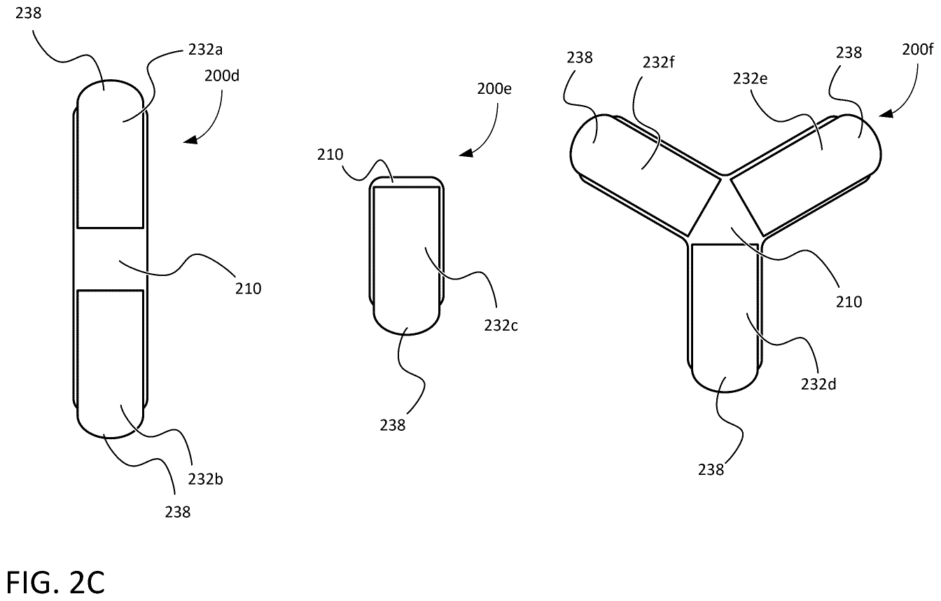

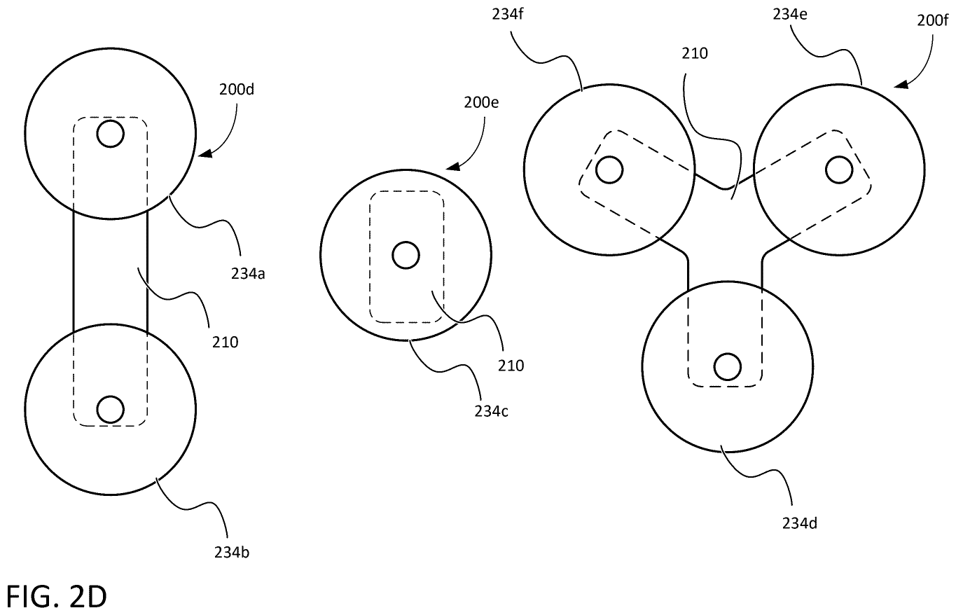

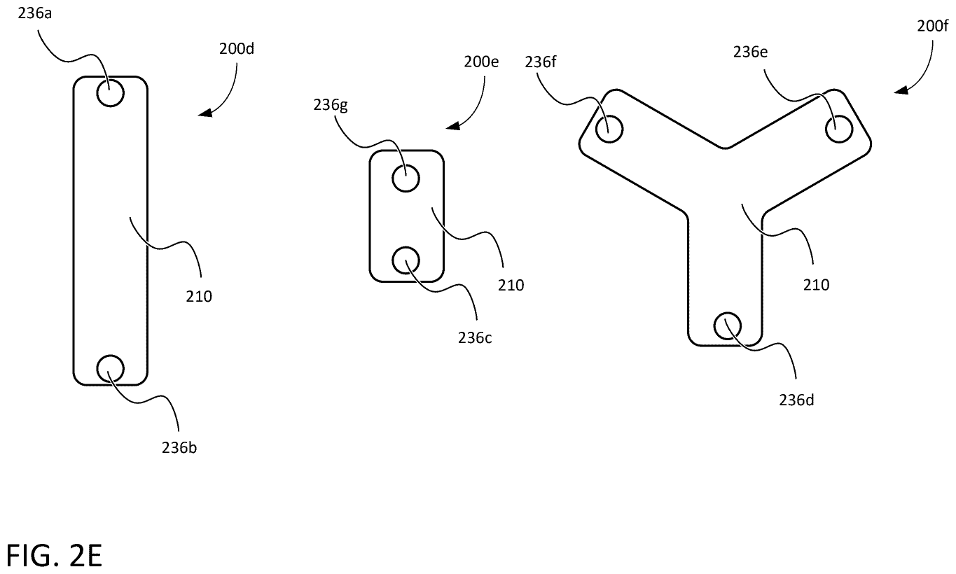

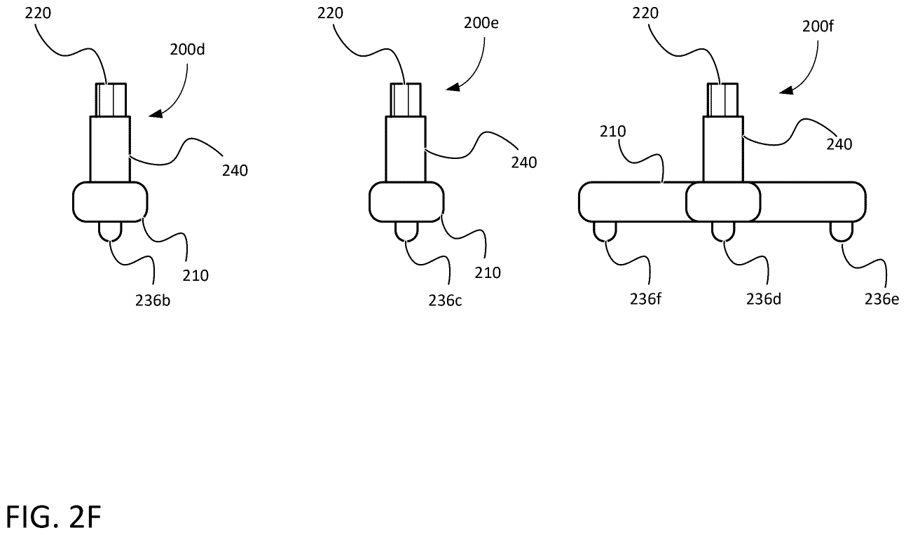

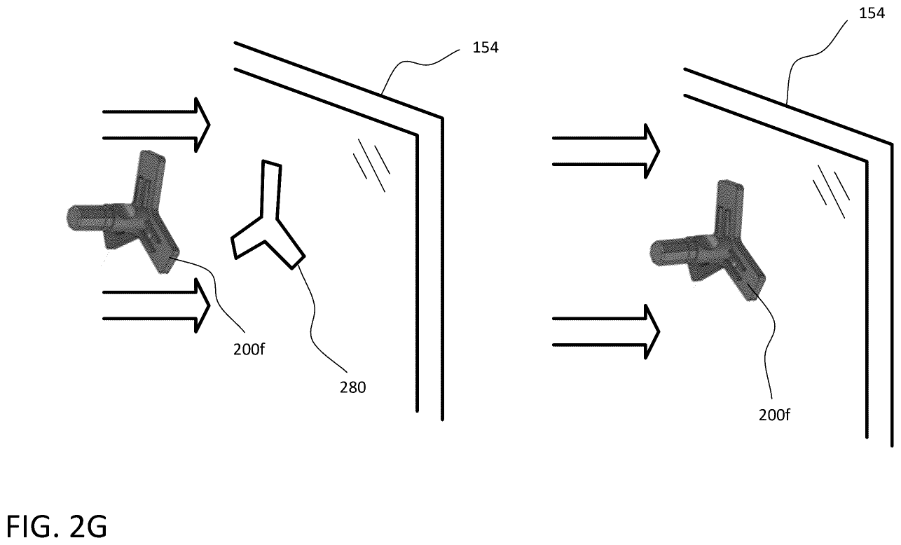

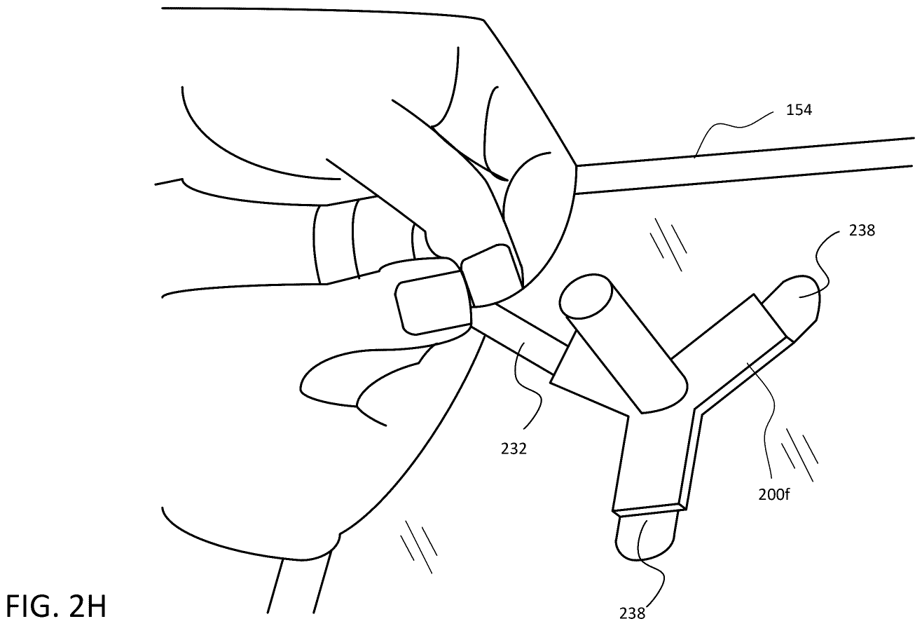

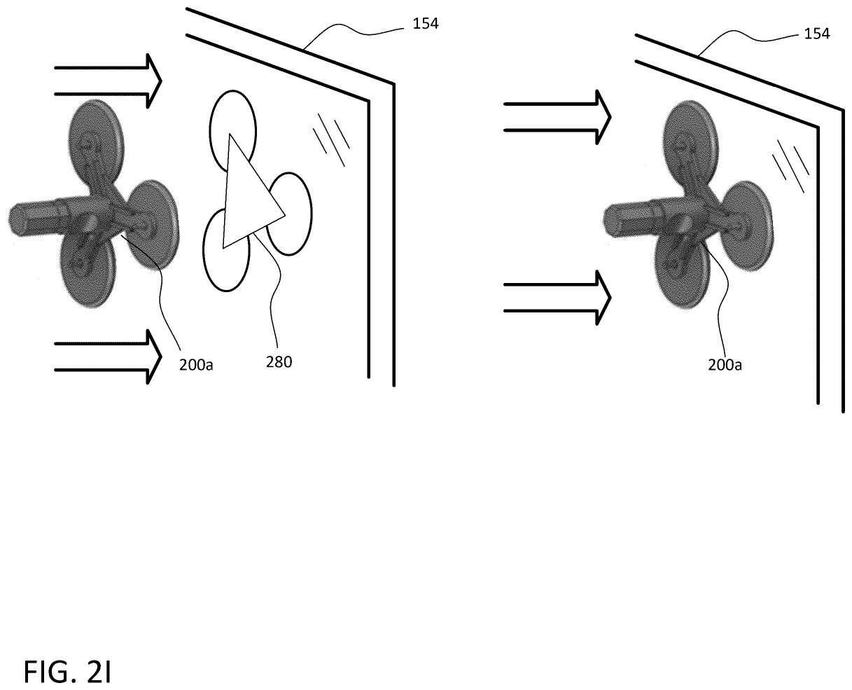

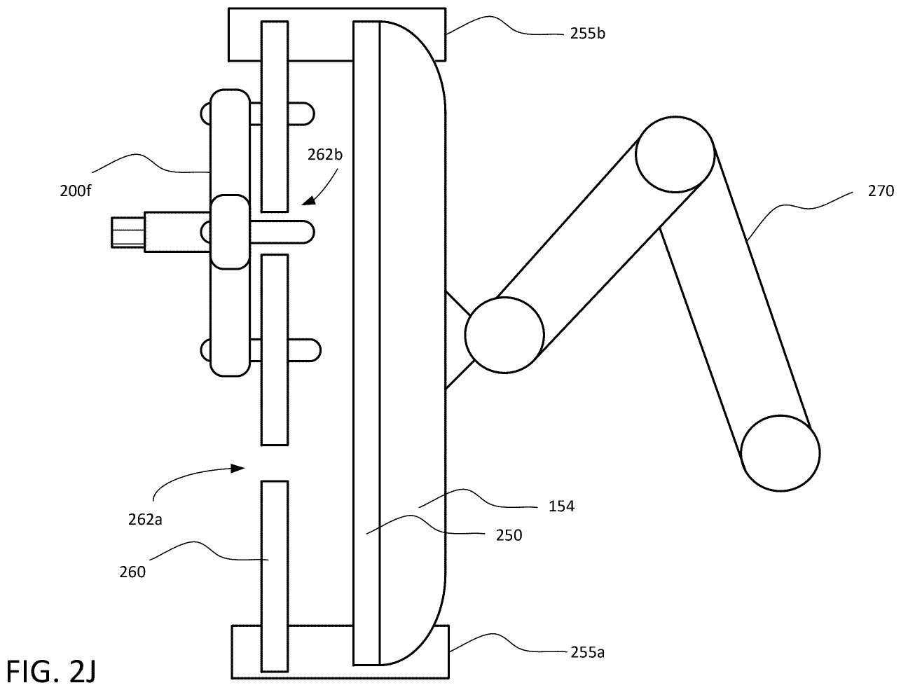

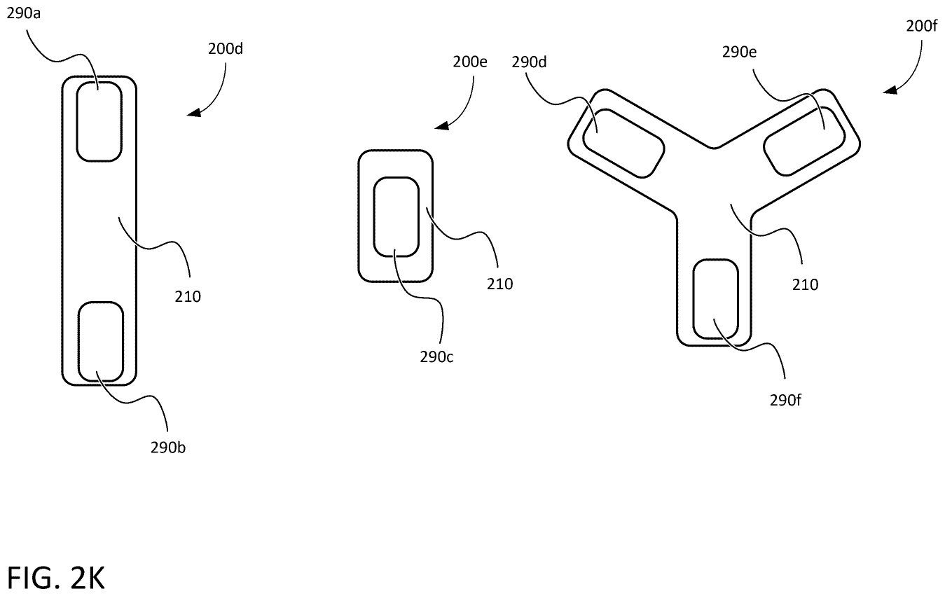

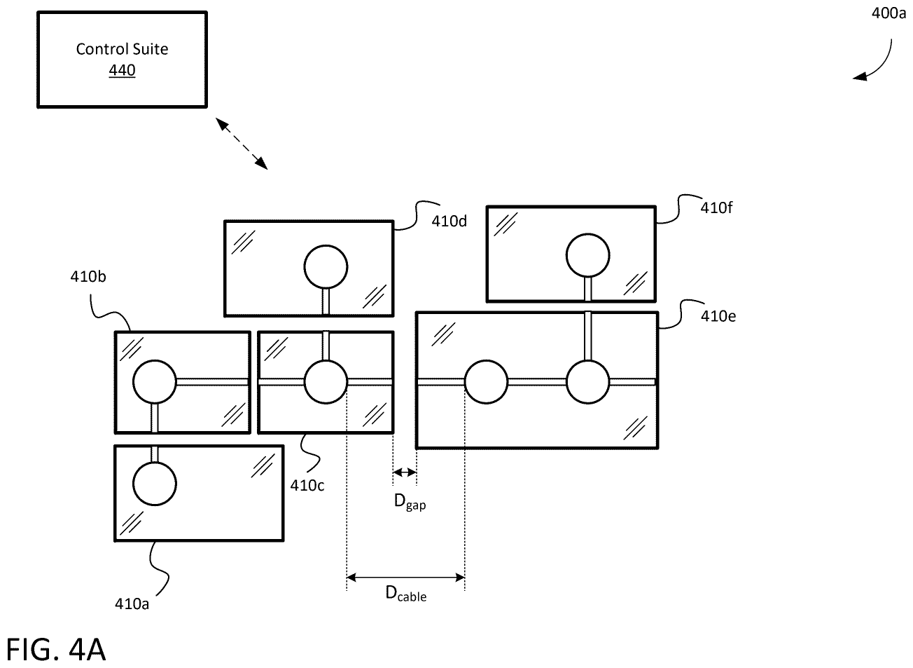

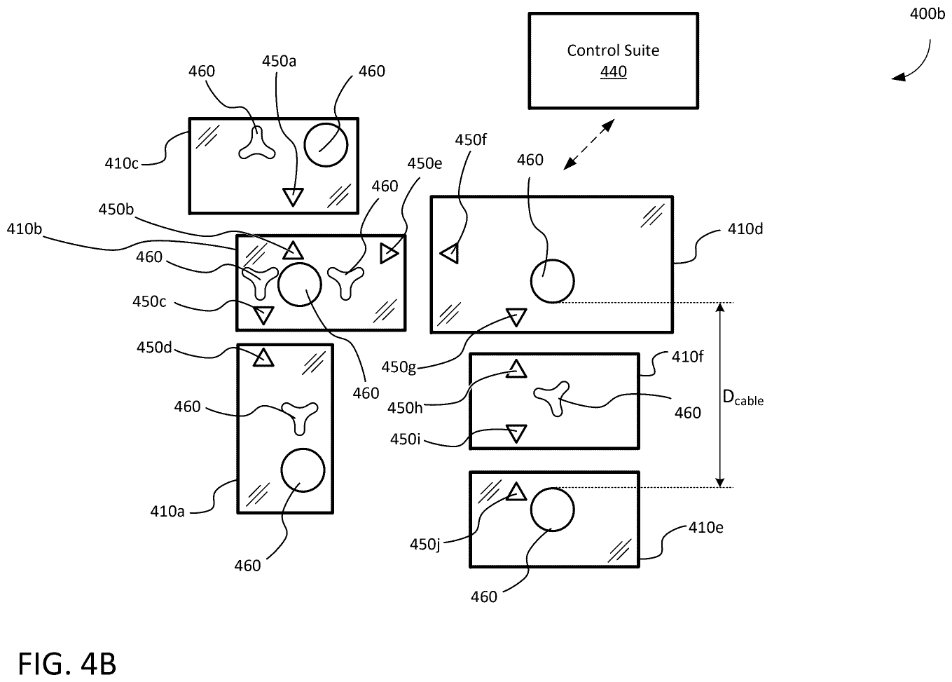

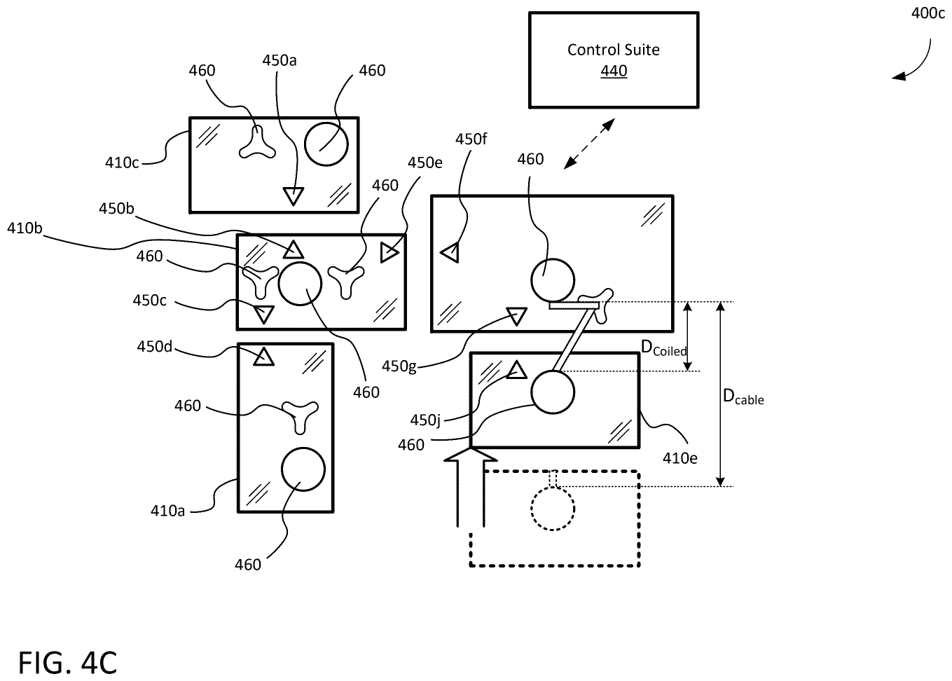

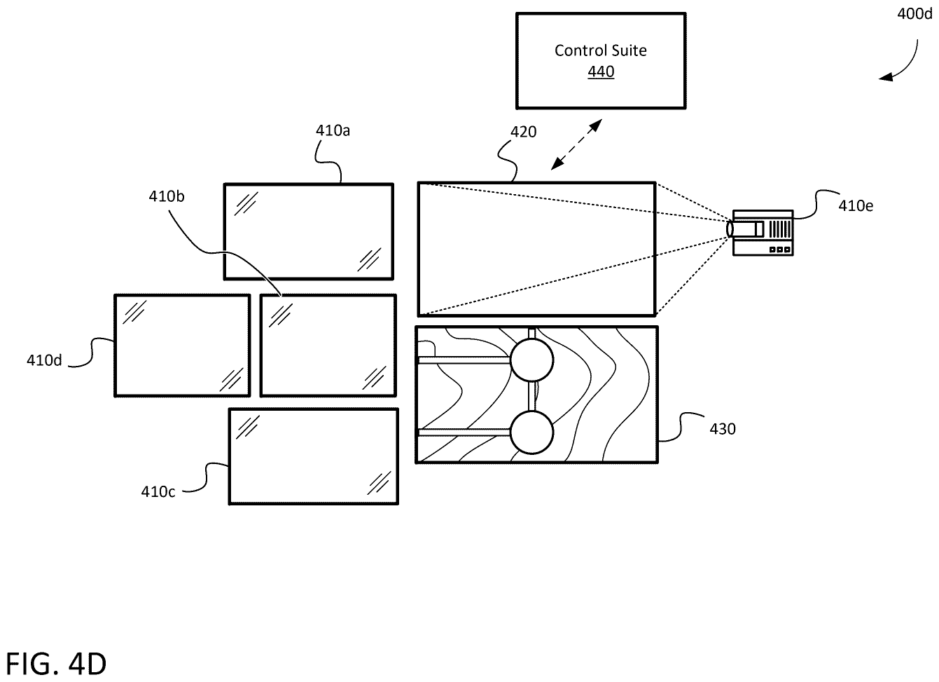

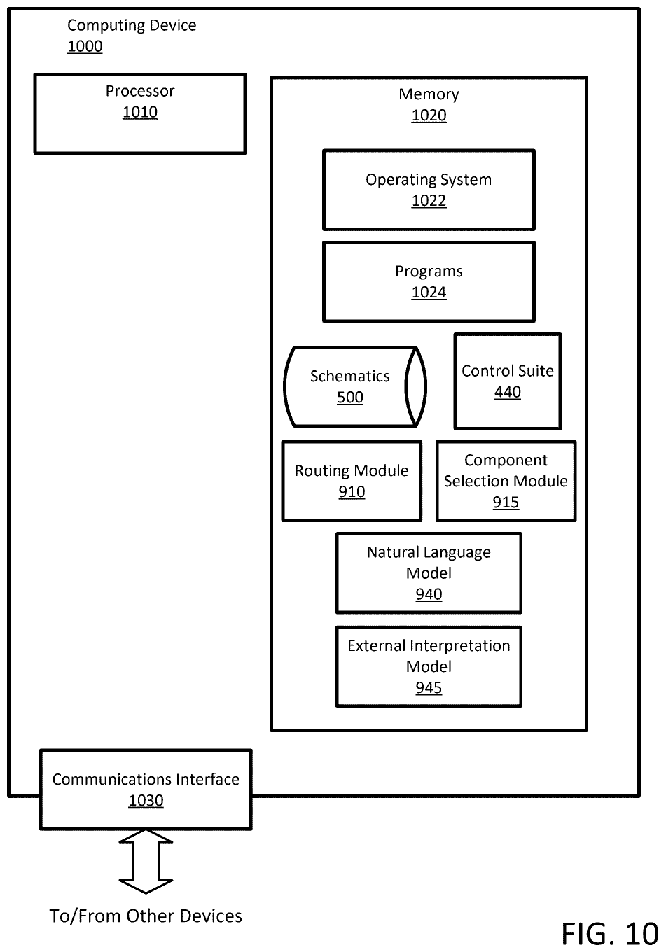

In various embodiments, a wire harness 100 may be constructed according to an engineering plan or drawing, which is translated to a fabrication system 150 used with one or more fixtures 160 to hold the components in place relative to the fabrication system 150. The fabrication system 150 may include one more control devices 152 (e.g., a computing device 1000 as in FIG. 10) used to generate an image on a display device 154 of the wire harness 100 to be constructed, icons (e.g., icon 280 in FIGS. 2H and 2J. icon 460 in FIGS. 4A-4D) for where to position the associated fixtures 160, and written instructions on one or more that a fabricator can use to build the wire harness 100 according to. Additionally or alternatively to visual instructions and feedback, the control device 152 may provide feedback or instructions via audio outputs.

One or more test devices 156a-d (generally or collectively, test devices 156) (e.g., a computing device 1000 as in FIG. 10) may be in communication with the control devices 152 and connect to the cables 110, splices 120 (if exposed), or connectors 130 of the wire harness 100 to determine whether the wire harness 100 has been constructed according to the engineering plan and that the components or signals carried thereby are within tolerances of specified values. In various embodiments, the control device 152 may also be or include a test device 156. The control device 152 controls, according to stored or user-defined instructions, the test devices 156 to generate various electrical signals (including values applied for voltages, waveform types, currents, timings, frequencies, data carried thereby, etc.) or optical signals (including wavelengths, amplitudes, waveform types, timings, data carrier thereby, etc.) to verify that the wire harness 100 includes the desired connections and that the components behave within expected thresholds. Accordingly, signals generated at one test device 156 may be measured at another test device 156 and compared against desired values (e.g., which ports received the signal, whether the signal was received within an acceptable signal to noise ratio (SNR) window, etc.).

Various peripheral devices 158, such as label printers, power supplies, user interfaces, and the like may also be included with the fabrication system 150 to allow for the presentation and confirmation of various layouts of wire harness construction.

In some embodiments, the control device 152 may be, or be in communication with, a central server or remote computing device that supplies images and build patterns for the wire harnesses 100 to be displayed on display devices 153. In some embodiments, the control device 152 collects various fabrication metrics during the construction of a wire harness 100, such as cycle time, throughput, labor productivity, defect rate, quality yield, first pass yield, overall operations effectiveness, downtime, training time, station/capacity use rate, and station activity. The control device 152 also logs the results of each test, and provides a means to analyze and compare test results over time, across different build stations, different operators, design iterations, build plan iterations, etc.

As distinguishable from the wiring of the wiring harness 100, the fabrication system 150 may include various “back wiring” to connect the various control devices 152, test devices 156, display devices 154, and peripheral devices 158, as well as external networks or computing devices. In addition or alternatively to back wiring, the various components of the fabrication system 150 may be in communication with one another or external devices via wireless communication means. The back wiring has been omitted from FIG. 1 so as to provide greater emphasis in the wiring on the wiring harness 100.

In some embodiments, the test process used with the fabrication system 150 may be used to verify that a fabricator installed all of the indicated components of a wire harness 100 in a desired layout and that all of the components are within acceptable tolerances (e.g., a cable 110 is installed between node₁ and node₂, and has a resistance within 10% of a nominal value). In some embodiments, the test process may be run in reverse-accepting a wire harness 100 into the test devices 156 of the fabrication system 150 and exploring what electrical or optical pathways are present in the device under test (e.g., a wire harness 100 of unknown design) to determine the signaling layout of the device under test. The signaling layout of a previously unknown design may be used to generate an engineering plan for later use, to identify a similar design (e.g., to modify an existing wire harness 100 to match another design), or to identify an over-design that incorporates the existing wire harness 100 as a sub-component thereof.

In various embodiments, the display devices 154 used by the control device 152 to output the plan for a fabricator to follow include a printer, which produces an image of the layout of the components of the wire harness 100 and associated fixtures 160 on a “formboard”, which may include paper, foamboard, cardboard, wood, sheet metal, etc., to provide a working surface with the desired image displayed thereon. The fabricator follows the layout printed onto the formboard to produce the wire harness 100, and may use several different formboards (each requiring storage and back wiring setup) to produce corresponding different wire harnesses 100. Additionally, as these formboards are individually designed for a given layout, updates to a design may require printing of a new formboard, scrapping any prior formboards and setup procedures, and re-layout of various back wiring.

In some embodiments, the display devices 154 used by the control device 152 to output the plan for a fabricator to follow include projectors, computer monitors, televisions, touch screen devices, etc., which may be periodically updated to illustrate subsets of the engineering plan at different times (e.g., to show a build sequence), changes made in the engineering plans, or highlights to portions of the engineering plans (e.g., to show a build sequence, identify non-compliant or missing components). Additionally, because build may specified in a step-by-step process with display of different components (or highlighting thereof) on electronic displays versus formboard displays, the fabricator may be provided feedback during the manufacturing process such that test operations are conducted while assembling and linking the various components. One added benefit of in-fabrication testing is that fabricators are less likely to batch process wire harnesses 100 (e.g., building several wire harnesses 100 or sub-assemblies thereof before running a “batch” of tests on the several wire harnesses 100; cf., single piece manufacturing/test), and instead produce one wire harness 100 and test that one wire harness 100 at a time; thereby reducing the potential ill effects of propagating build errors.

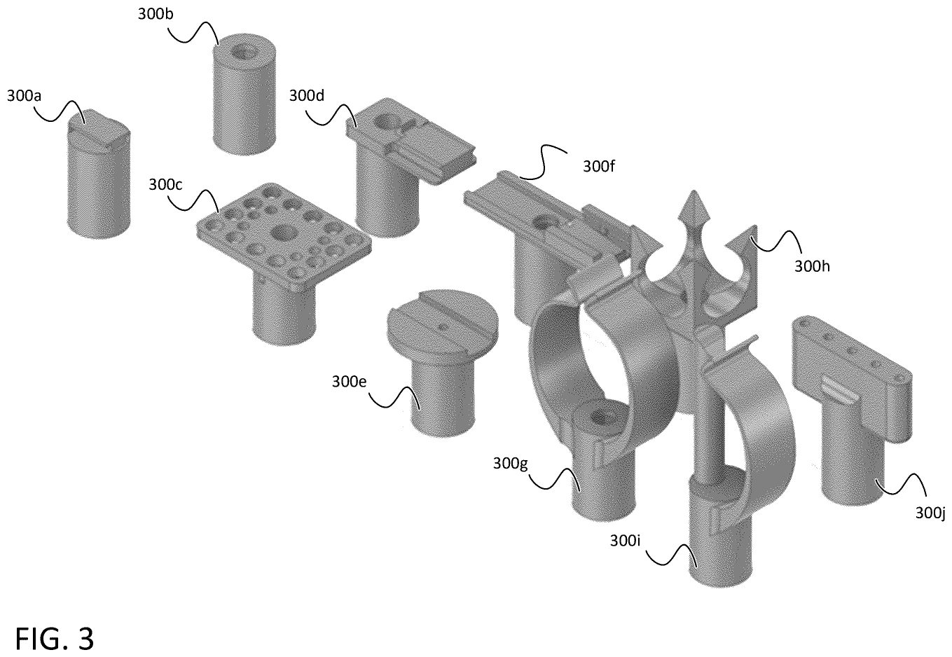

FIGS. 2A-2B illustrate various example mounts 200a-g (generally or collectively, mounts 200) for the fixtures 160 used in conjunction with the display devices 154. As used herein, a fixture 160 may describe any device used to extend from a formboard to hold components of an article of manufacture or a fabrication system 150 in place relative to the formboard. In various embodiments, a fixture 160 may be a multi-part modular construction, having a mount 200, such as those shown in FIGS. 2A-2B that is configured to affix the fixture 160 to the formboard, and a head (e.g., a head 300 as shown in FIG. 3) connected to the mount 200 to hold the component of the article of manufacture or the fabrication system 150. One or both of the mounts 200 and heads (300) may be fabricated via additive manufacturing (e.g., 3D printed), but may include components made via molding, casting, subtractive manufacturing, or the like.

FIG. 2A illustrates a variety of different form factors that a mount 200a-g may take, although the present disclosure contemplates that more and different form factors may be used. As shown in FIG. 2B, different mounts 200 may offer different sizes and shapes for respective feet 210 to interface with the display device 154 of the fabrication system 150, but each offer a commonly sized interface 220 to allow various heads (300, discussed in relation to FIG. 3) to be secured thereon to hold various cables 110 in place according to the plan for wire harness construction displayed on the display device 154. FIGS. 2C-2F and 2K discuss various mounting hardware 230 for selectively attaching and detaching the mounts 200 from a surface of a display device 154 for setup, adjustment, and take down of the fabrication system 150 when constructing a wire harness 100 or other article of manufacture. In various embodiments, the mounting hardware 230 variously include viscoelastic adhesive strips 232, suction cups 234, magnets 290, and pegs 236. FIGS. 2G-2J illustrate various examples of the mounts 200 being affixed to or removed from display devices 154.

In various embodiments, despite increasing inventory overhead for the types of fixtures 160 to choose between, a fabricator may choose between multiple different types of mounts 200 based on the amount of space available on the display device 154, the type of display device 154 (e.g., a printed wooden formboard vs. a dynamic display formboard), and the height of a neck 240 that separates the foot 210 from the interface 220. As will be appreciated, mounts 200 with larger feet 210 occupy more real estate on the surface of the display device (and may overlap an edge thereof), but generally offer greater support strength for heavier collections of cables 110 compared to mounts 200 with smaller feet 210; offering a design tradeoff.

Despite offering various sizes of feet 210 and mounting hardware 230, each of the mounts 200 may offer a uniformly sized interface 220 to engage with a shared set of available heads (300). In various embodiments, the perimeter of the interface 220 generally describes a regular polygon with six, eight, ten, or twelve sides. The polygonal perimeter allows a fabricator to attach the heads (300) to the mounts 200 at one of several fixed angles-thereby preventing rotation once attached, but permitting rotation to a desired angle relative to the mount 200 before attachment.

FIG. 2C illustrates an underside view of three mounts 200d-f using viscoelastic adhesive strips 232a-f as the mounting hardware 230. FIG. 2D illustrates an underside view of three mounts 200d-f using suction cups 234a-f as the mounting hardware 230. FIG. 2E illustrates an underside view of three mounts 200d-f using pegs 236a-g as the mounting hardware 230, and FIG. 2F illustrates a side view of the three mounts 200d-f using pegs 236a-g as the mounting hardware 230. FIG. 2K illustrates an underside view of three mounts 200d-f using magnets 290 as the mounting hardware 230. In various embodiments, the fabricator may freely swap the mounting hardware 230 used by a given mount 200 for different mounting hardware 230 (e.g., removing suctions cups 234 and then using pegs 236 or viscoelastic adhesive strips 232) or to replace worn mounting hardware 230 (e.g., to replace a cracked suction cup 234 that no longer holds vacuum with a new suction cup 234, to replace a removed viscoelastic adhesive strip 232, etc.). In various embodiments, the pegs 236 may be permanent (or semi-permanent) projections of the foot 210 or may be fasteners inserted through a hole in the foot 210 (e.g., nails, screw, pegs) to hold onto the display device 154 in a predefined hole therein or to form a hole therein (e.g., through a wooden formboard).

As will be appreciated, depending on the grip strength desired between the foot 210 and the surface of the display device 154, the composition of the mounting surface (e.g., magnetic or non-magnetic), and the available space on an associated foot 210, a fabricator may use one or more instances of the mounting hardware 230. For example, a fabricator may select a foot 210 that has the space to mount one, two, three, etc. viscoelastic strips 232, suction cups 234, magnets, or pegs 236. Additionally, the fabricator may freely swap the mounting hardware 230 used in a given mount 200, for example by inserting/removing pegs 236 through pre-formed holes in the feet 210 that are also configured to hold an extension arm of a suction cup 234 inserted therethrough (either by friction or the use of a cotter pin or similar) or be covered by a viscoelastic strip 232.

In various embodiments, the viscoelastic adhesive strips 232 are provided with an initial covering on two sides, which is removed to mount the viscoelastic adhesive strips 232 to the foot 210 on a first (base) side, and to a surface of a display device 154 on a second (mounting) side. A release tab 238, which may retain a cover to prevent adhesion to any surfaces, projects outward from the foot 210, which a fabricator may grip and pull on to stretch the material of the viscoelastic adhesive strip 232 to release the bond to the foot 210 and the surface of the display device 154.

One example of a material useful in a viscoelastic adhesive strip 232 is 3M Stretch Release 6657-150, which may be commercially available from 3M Co. (of Maplewood, Minnesota, USA) under the brand name of “COMMAND™” strips.

In various embodiments, one mount 230 may optionally be used with several different types of mounting hardware 230 by replacing the mounting hardware 230 with another type.

FIGS. 2G and 2H illustrate the affixing and removal, respectively, of a mount 200f using viscoelastic strips 232 as the mounting hardware 230 to a display device 154. An icon 280 is displayed by the display device 154 (e.g., as a generated image on an Liquid Crytal Display (LCD)) that shows an fabricator where the mount 200 is to be placed on the display device 154. In various embodiments, when the display device 154 includes touchscreen functionality, the display device 154 may provide feedback to the fabricator for whether the mount 200 has been properly placed over the icon 280, or remove the icon 280 from display once the mount 200 is affixed in the indicated location.

In various embodiments, the icons 280 may be shaped and sized similarly to the feet 210 of the mounts 200 (e.g., as in FIG. 2G) or may be more stylized (e.g., as in FIG. 2I) to indicate the mounting hardware 230 to be used and where the mounting hardware 230 will be located on the display device 154.

As shown in FIG. 2H, a fabricator pulls the tab 238 of the viscoelastic strip 232 to break the bond with the display surface 250 of the displays device 154, after which the mount 200 may have new viscoelastic strips 232 applied to the foot 210 for reuse and repositioning.

FIG. 2I illustrates the affixing of a mount 200a using suction cups 234 as the mounting hardware 230 to a display device 154.

FIG. 2J illustrates the affixing of a mount 200f using pegs 236 as the mounting hardware 230 to a display device 154. In various embodiments, a pegboard 260 made of a transparent or translucent material with regularly spaced (or pre-defined spacing in any pattern) predefined holes 262a-b (generally or collectively, holes 262) is held in front of a display surface 250 of a display device 154 so that images (e.g., icons 280) displayed via the display surface 250 may be seen through the pegboard 260, and the pegs 236 selectively placed through the predefined holes 262 to align the mount 200 (or components of an article or manufacturing being fabricated) with an image underneath.

Various spacers 255a-b may be used to hold the pegboard 260 away from the display surface 250 so that the pegs 236 do not contact (or push through or otherwise damage) the display surface 250.

In various embodiments, various positioning arms 270 may be connected to a back or any other side than the display surface 250 to connect any back wiring to the display device 154 and allow a fabricator to reposition the display device 154 in the environment (e.g., relative to a work surface, other display devices 154, etc.).

Although illustrated in FIG. 2J with the mount 200f using pegs 236 as the mounting hardware 230, mounts 200 using viscoelastic strips 232 as the mounting hardware 230 may also be used with display devices 154 using pegboards 260 (e.g., as a protective layer or for dual purpose mounting), as the viscoelastic strips 232 may be placed over the predefined holes 262 and bond to the area of the pegboard 260 surrounding and defining the holes 262 with minimal adverse effect for bonding strength.

FIG. 3 illustrates various example heads 300a-j (generally or collectively, heads 300) for the fixtures 160 used in conjunction with the display devices 154. Each of the heads 300 may be mounted, at various rotational angles, on any one of the example mounts 200 discussed in relation to FIGS. 2A-2J, and may be configured to hold and route various cables 110 therein. A fabricator may mix and match the various heads 300 with the various mounts 200 to hold the cables 110, splices 120, and connectors 130 in place according to a visualization displayed on the fabrication system 150. Generally, each head 300 defines, on an underside thereof, a cavity that is matched in shape and size to an interface 220 for the available mounts 200, so that a fabricator may slide the head 300 onto a mount 200 with a desired relative angle between the two components, and slide the head 300 off from the mount 200 when fabrication is complete (e.g., for reused in a different project) or to make adjustments during fabrication.

FIGS. 4A-4D illustrate various examples 400a-d of reconfigurable multi-display handling for a fabrication system 150, according to embodiments of the present disclosure. Although FIG. 1 illustrates a fabrication system 150 using one display device 154, the present disclosure contemplates that multiple display devices 154 may be used in connection with one another, for example, such as when using multiple dynamic displays 410a-f (generally or collectively, dynamic displays 410).

Each of the dynamic displays 410 may be in communication with a central control system 440 (e.g., provided by a control device 152 or central server) that identifies the number, aspect ratio, size, and display resolutions of the various dynamic displays 410 to identify how to scale the drawing to the available screen space, where to display the elements of the drawing using the available screen space (and avoiding edges so that fixtures 160 can be secured to the screens), and how to best present the build sequence to a fabricator. In various embodiments, the control system 440 is in bidirectional communication with the various dynamic displays 410, control devices 152. and test devices 156 deployed in the fabrication system 150 to identify the various features of the available dynamic displays 410 and what stage of fabrication the wire harness 100 is currently in.

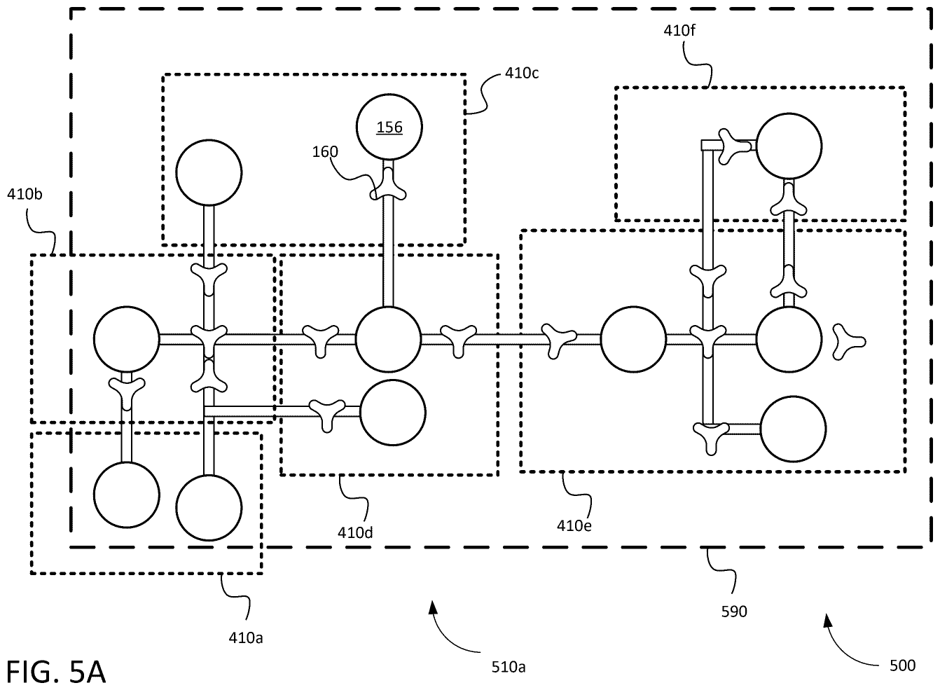

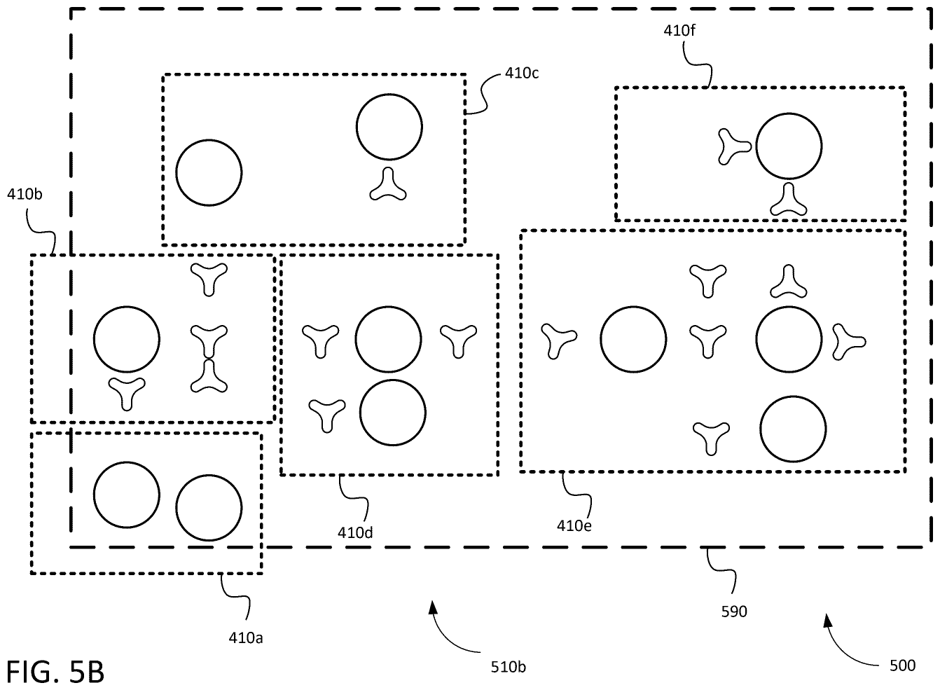

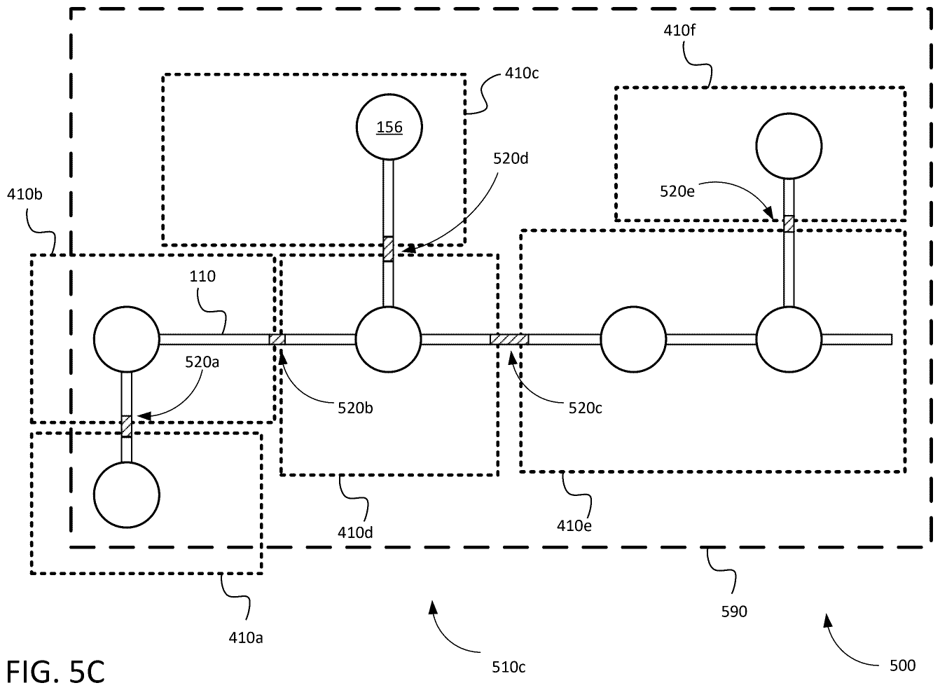

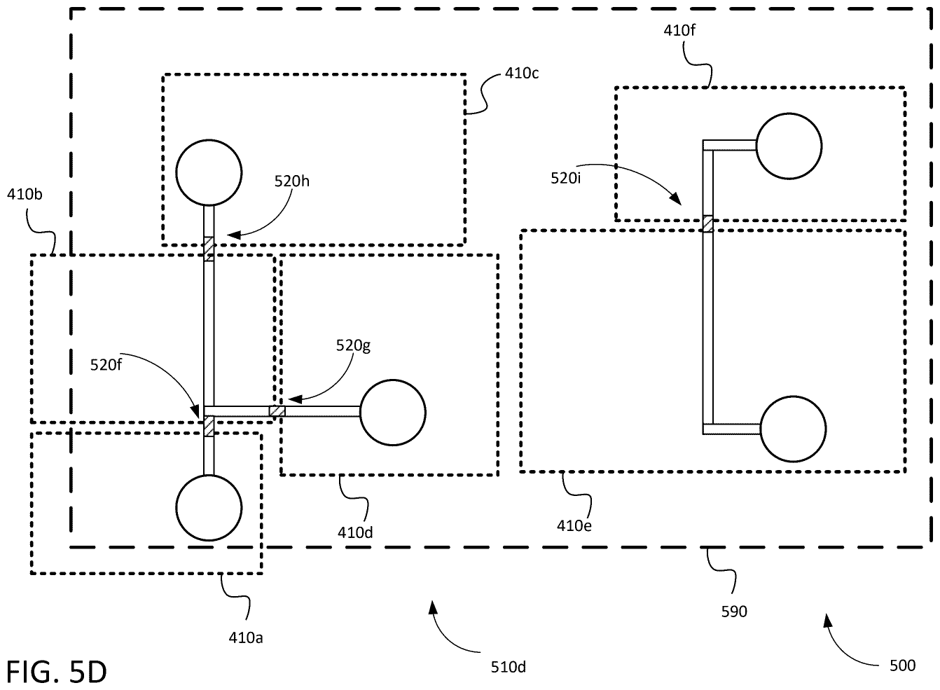

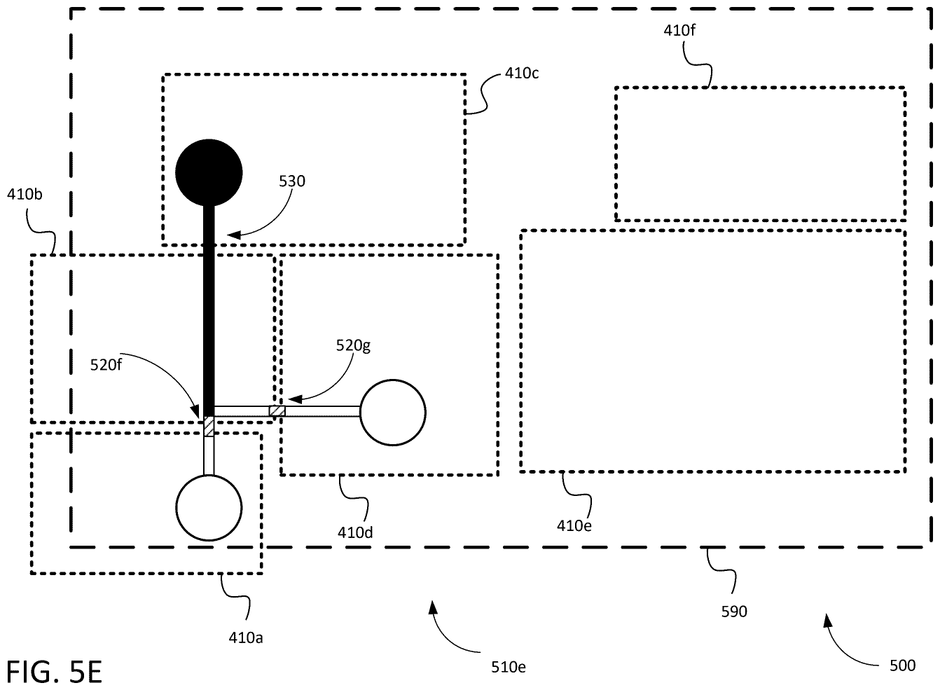

As shown in FIG. 4A, the drawing of the wire harness 100 to be constructed is spread out over a plurality of dynamic displays 410a-f; however, because the screens may include frames or margins in which an image cannot be displayed, the control system 440 determines where the image cannot be displayed or fixtures 160 cannot be affixed to the screens to arrange where the various elements are displayed and to be mounted (see, FIGS. 5A-5E and associated discussion). The display of the image relative to the image accounts for the areas that cannot (or are not) displayed between the dynamic displays 410, resulting in some of the conceptual length of the cables 110 (D_{cable}) not being displayed for a gap distance (D_{gap}) between two or more dynamic displays 410.

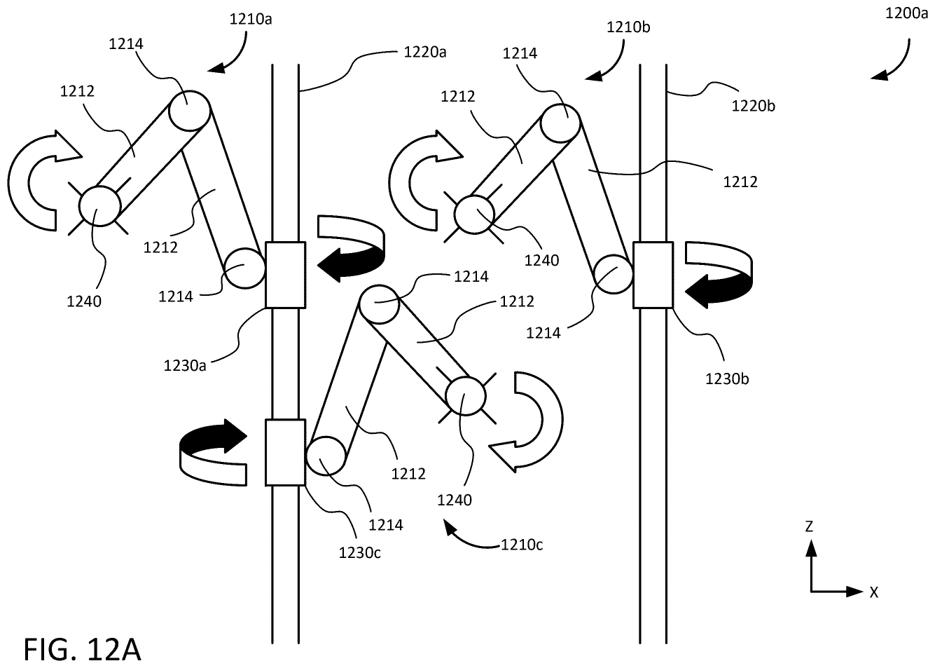

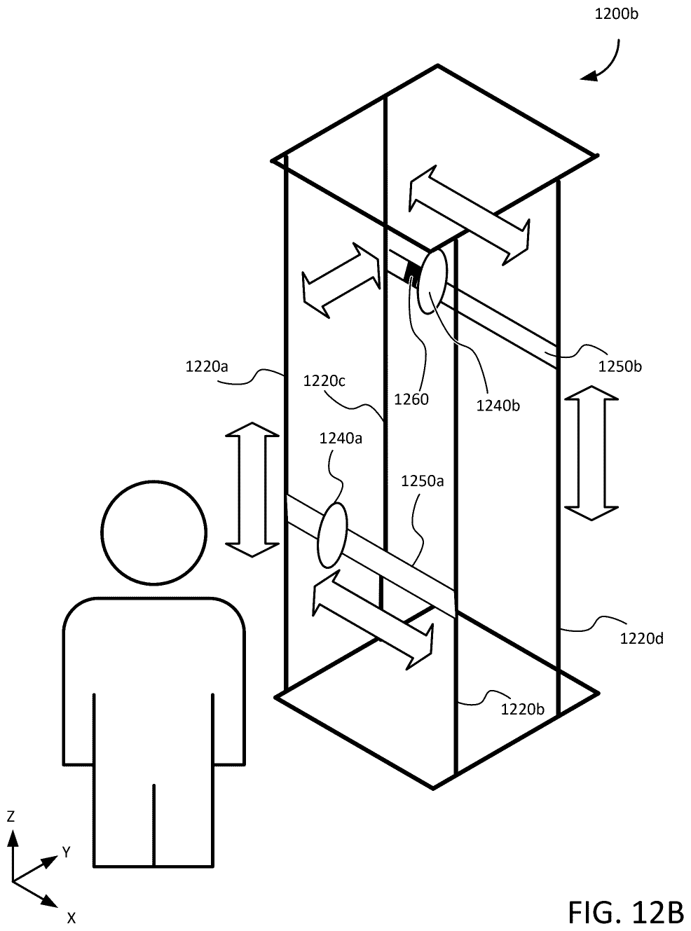

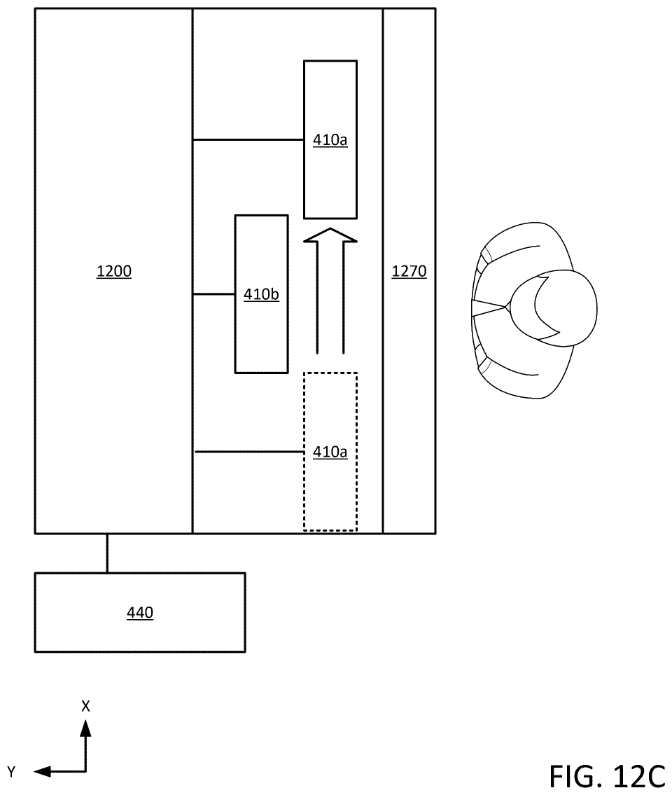

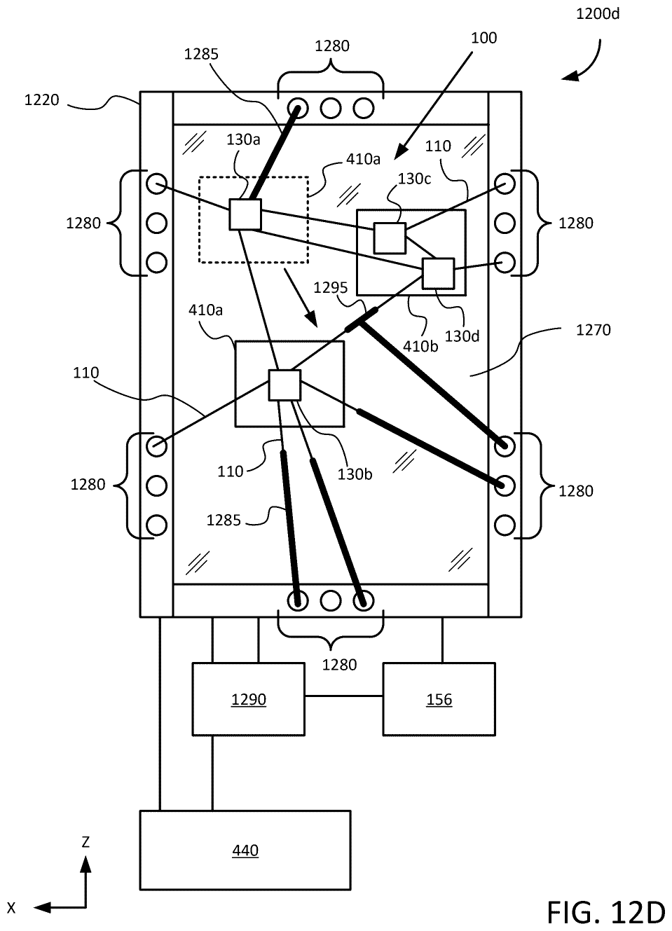

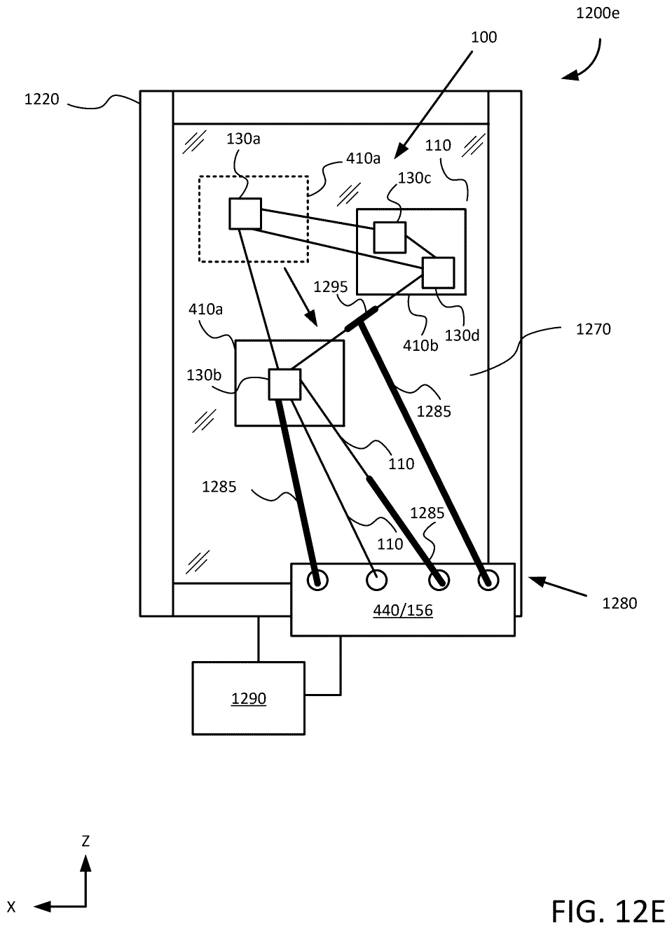

As shown in FIGS. 4B and 4C, the control system 440 may identify how the various dynamic displays 410 are to be located relative to one another, and may display alignment markers 450a-j (generally or collectively, alignment markers 450) to align the various dynamic displays 410 relative to one another (or alignment features on the static displays 430, if used). Additionally, the control system 440 may identify when a dynamic display 410 is superfluous for setting up the wire harness 100, such as the sixth dynamic display 410f in FIG. 4B that only carries a fixture 160 and a cable 110 that may be coiled. Accordingly, with the removal of the sixth dynamic display 410f in FIG. 4C, the fifth dynamic display 410e may be brought closer to the fourth dynamic display 410d (e.g. by a coiled distance (D_{coiled}) of the cable 110 versus the full length (D_{cable}) of the cable 110), thereby saving space in the manufacturing environment. In some embodiments, the control system 440 may instruct the fabricator to relocate a fixture 160 (or use an alternative fixture 160) and coil or otherwise reroute the cable 110 that previously occupied the now-removed sixth dynamic display 410. In some embodiments, the control system 440 may automatically move the display devices 410 (e.g., via associated motors in a display handling system, such as those discussed with respect to FIGS. 12A-12E).

The dynamic displays 410 may include various televisions, computer monitors, touch screen devices, and projectors (with associated projection surfaces 420) of various sizes and aspect ratios, and may be used in conjunction with various static displays 430, such as a wooden formboard, as shown in FIG. 4D. In various embodiments, static displays 430 may display commonly used “core” elements of several different wire harnesses 100 that a fabricator can expand from using various dynamic displays 410 that show customized, updated, or harness-specific build elements.

FIGS. 5A-5E illustrate an example schematic 500 of a wire harness 100 to be constructed as modified for sequential display over a plurality of dynamic displays 410a-f, according to embodiments of the present disclosure. FIG. 5A illustrates an example schematic 500, including the locations for each fixture 160, cable 110, and test device 156 to be affixed during the assembly of an example wire harness 100. The schematic 500 occupies a canvas 590 in the application used to generate, display, and edit the schematic 500, but is divided across several dynamic displays 410a-f having display areas that do not necessarily overlap with or show all of the canvas 590. Stated differently, based on the available screen real estate on the dynamic displays 410, the dynamic displays 410 may omit displaying some portions of the canvas 590 or may display information outside of the canvas 590.

As will be appreciated, the amount of detail shown in the entire schematic 500 shown in FIG. 5A may be distracting to a fabricator, and not all of the information is needed at the same time. Accordingly, as shown in FIG. 5B, a first sequence 510a of the schematic 500 is provided on the various dynamic displays 410, showing where the fixtures 160 (identified with tri-footed icons) and test devices 156 (identified with circular icons) are to be located as a first step in the fabrication process.

Once the fixtures 160 and test devices 156 are in place, the dynamic displays 410 may show a second sequence 510b of the schematic 500, as is illustrated in FIG. 5C, which removes display of the locations to place fixtures 160 and test devices 156, and instead illustrates a first network 140a; showing the test devices 156 (identified with circular icons) and cables 110 (identified with rectangular icons) to connect thereto. As will be appreciated, various splices 120 and connectors 130 may be present in the first network 140a, but are omitted in the illustration for case of understanding. Because the cables 110 of the first network 140a extend across the gaps between the dynamic display devices 410, the second sequence 510b of the schematic 500 identifies one or more non-displayed regions 520a-e (generally or collectively, non-displayed regions 520) whose length should be accounted for in the display of the portions of the wire harness 100 to be constructed, but are not to be displayed. The precise dimensions of the non-displayed regions 520 may vary based on the frames/margins of the display devices 154 or distances between the display regions thereof.

FIG. 5D illustrates a third sequence 510c of the schematic 500, removing display of the first network 140a shown in FIG. 5C and inserting display of a second network 140b and a third network 140c. Similarly, to the first network 140a, the control system 440 determines the locations of additional non-displayed regions 520f-i that correspond to portions of the cables 110 that extend over gaps between the dynamic display devices 410 whose lengths need to be accounted for, despite not being displayed.

FIG. 5E illustrates a fourth sequence 510d of the schematic 500, highlighting a section 530 of the second network 140b that, on test, has not behaved according to a desired signaling characteristics (e.g., a short, an open circuit, a SNR outside of an acceptable range), which may indicate a faulty cable 110, mis-installation of an element of the network 140, a fault in the test device 156, or the like. By highlighting this non-conformance, the fourth sequence 510d may aid in the fabricator taking corrective action. Highlighting may be accomplished via a change in color, cycling or flashing a change in color, the addition of display elements pointing to an element of interest, combinations thereof, and the like. In addition or alternatively to the visual highlighting provided by the dynamic displays 410, the fabrication system 150 may provide audible or haptic feedback to draw attention to certain portions of the wire harness 100 under construction.

In various embodiments, the fabricator may cause the control system 440 to advance between the various sequences of a build by indicating that a current sequence in the build is believed to be complete, and that test should be initiated. On successful completion of the test, the control system 440 then advances display to the next sequence (e.g., as from FIG. 5C to FIG. 5D), while on unsuccessful completion of the test, the control system 440 may attempt to highlight potential sources for a non-conformance that lead to unsuccessful completions of the test (e.g., as from FIG. 5D to FIG. 5E).

In various embodiments, the control system 440 automatically interfaces with the dynamic displays 410 to identify where the components to be displayed on the screens should be located, and generates the non-displayed regions 520 of the image accordingly. The non-displayed regions 520 generally conform to the negative space in the canvas 590 that is not shown as overlapping with the areas of display of the dynamic displays 410, and specifically to the highlighted portions 520a-e of the cables 110 that are present in the canvas 590 and outside of the areas of display. Similarly, the control system 440 may identify the order in which the sequences are to be presented to aid in an optimized build order (e.g., whether to display some/all of the first network 140a before displaying some/all of the second network 140b and third network 140c). In various embodiments, the control system 440 may use an artificial intelligence (AI) module or heuristics to determine the locations and orders in which to display the elements of the schematic 500, and may cooperate with a human user to manually enter some or all of the element locations or orders (e.g., with semi-automated data aids).

Although the schematic 500 is shown herein as a still image, the present disclosure contemplates that the schematic 500 or sequences 510 thereof may include animations for some or all of the elements shown therein.

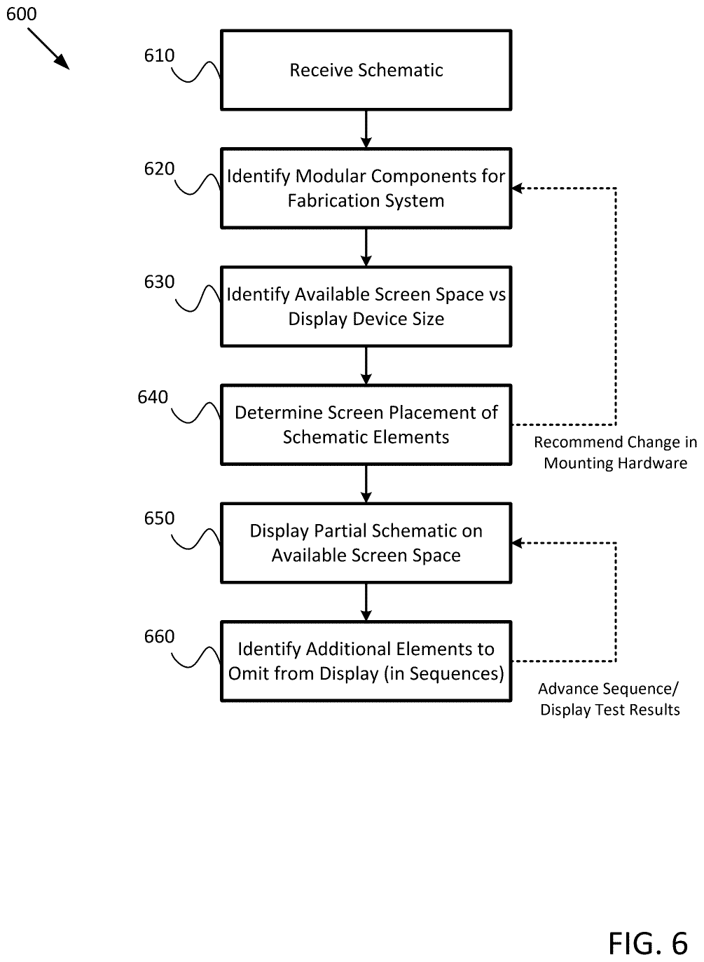

FIG. 6 is a flowchart for an example method 600 of operating reconfigurable multi-display setups for a fabrication system, according to embodiments of the present disclosure.

At block 610, the fabrication system 150 receives a schematic 500 for an article of manufacture, such as a wire harness 100 for electrical, optical, fluid (e.g., pneumatic, hydraulic, or medical) networked transmission, to be fabricated thereon.

At block 620, the fabrication system 150 identifies the modular components that the fabrication system 150 should include for a fabricator to construct the article of manufacture indicated in the schematic 500, including a number and type of display devices 154, test devices 156, and fixtures 160.

In various embodiments, the fabrication system 150 identifies the number and types of display devices 154 to display the schematic 500 based at least in part on a scaling factor applied for the display of the schematic 500 (e.g., X:1, 1:1, or 1: X displayed image to physical elements), a density of elements shown in a schematic 500, a total area occupied by the elements in the schematic 500, a total area of the schematic 500 (including empty area or areas occupied by notes), display devices 154 present in the manufacturing environment (and not engaged with another active fabrication system 150), any designer-specified display devices 154 to use, and combinations thereof.

In various embodiments, the fabrication system 150 identifies the number and types of test devices 156 to include based at least in part on the number of terminal ends, splices 120, or connectors 130 included with the cables 110; the types of tests defined by a designer for the wire harness 100; whether any test devices 156 are integrated or connected to any of the display devices 154, and combinations thereof.

In various embodiments, the fabrication system 150 identifies the number and types of fixtures 160 to use to hold the cables 110 and other components in place relative to a displayed image of the schematic on various display devices 154 based at least in part on the material of the display surface for the display devices 154, weights of the various components to be held by the fixtures 160, the number of fixtures 160 holding a given component, where the fixtures 160 are to be located relative to edges of the display devices 154, where the fixtures are to be located relative to one another, any designer-specified fixtures 160 to use and combinations thereof. In various embodiments, the fabrication system 150 may specify one of both of the mounts 200 and the heads 300 for the fixtures 160 to use.

At block 630, the fabrication system 150 determines an available screen space on the selected display devices 154 relative to the size of the display devices 154. In various embodiments, a given display device 154 have a physical length and width that is greater than a display area of that display device 154. Additionally or alternatively, the display device 154 may have a fixture-placement margin that prevents the placement of fixtures 160 within a given distance of a frame or edge of the display area. In various embodiments, the fabrication system 150 identifies the aspect ratios of the display devices 154, absolute sizes of the display devices 154, whether a display device 154 is indicated as rotatable (e.g., on a pivotable harness, a controllable projector, etc.) to present an aspect ratio at an angle of rotation, and combinations thereof.

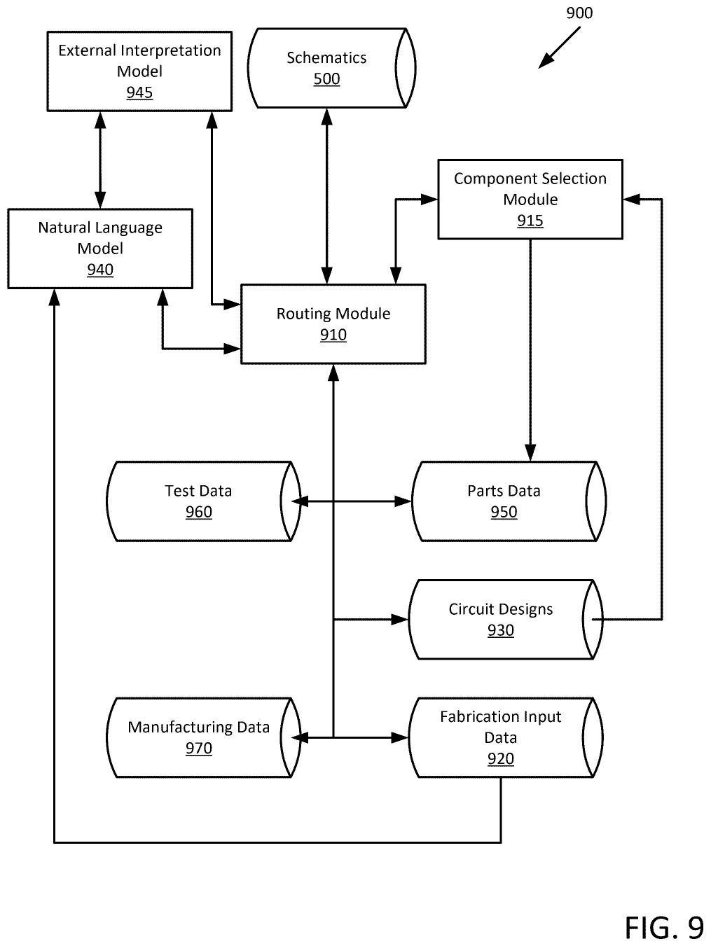

At block 640, the fabrication system 150 determines a screen place of the schematic elements (e.g., items represented in the schematic 500) on the selected display devices 154. In various embodiments, the fabrication system 150 uses one or more AI modules (e.g., see FIG. 9) to determine how to place the schematic elements for display and the physical elements to be held on the display devices 154.

In various embodiments, when the schematic is to be placed across two or more display devices 154, the fabrication system 150 places the components such that the physical distance between adjacent display spaces is occupied only by cable 110. For example, a non-displayed region 520 of the schematic 500 may overlap with a gap between a first dynamic display 410a and a second dynamic display 410b or the respective margins/frames of the dynamic displays 410, and may include unoccupied areas of the schematic 500, portions of the schematic 500 including metadata or written notes, or portions of the schematic 500 corresponding to a cable 110, but not include portions of other elements of the schematic (e.g., where to position fixtures 160, test devices 156, splices 120, or connectors 130).

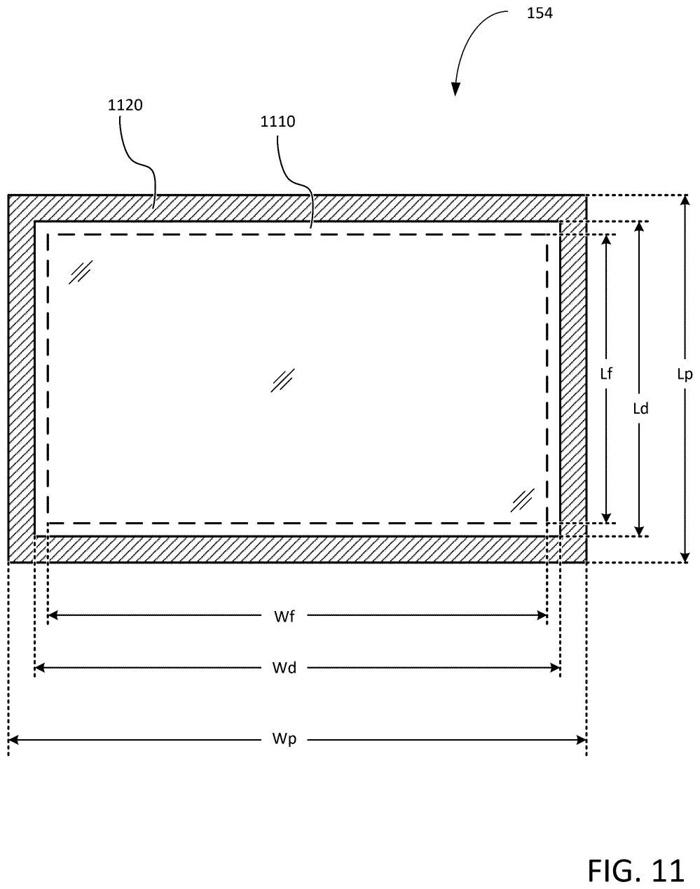

In various embodiments, when the schematic is to be placed across two or more display devices 154, the fabrication system 150 places the fixtures 160 within a fixture space (e.g., within a boundary of the display surface that offers sufficient space to bond to). For example (as shown in FIG. 11), not all of the physical device for the dynamic display 410 may be capable of displaying portions of a schematic (e.g., a frame or a margin) and even then, not all of the display space of the dynamic display 410 may be available to place a fixture 160 on. For example, an edge of the physical device or a frame around the physical device may disrupt the ability to reliably affix a suction cup 234 on or over that space, the space may lack holes for pegs 236 to be inserted into, etc. In some embodiments, when using viscoelastic strips 232 as the mounting hardware 230, the fabrication system 150 may permit the mounting hardware to be closer to an edge of a dynamic display 410 or even overlap the edge of a dynamic display 410, thereby increasing the mountable space on the dynamic display device 410 over other mounting hardware 230. For example, a tri-lobed mount 200f may be mounted such that two lobes are affixed via viscoelastic strips 232 (e.g., viscoelastic strips 232e and viscoelastic strips 232f) to the mounting surface of a dynamic display 410, while the third lobe extends past an edge of the display surface.

In various embodiments, when the fabrication system 150 initially selected suction cups 234 for use as the mounting hardware 230 per block 620, the system may recommend or redetermine that one or more fixtures 160 are to use viscoelastic strips 232 as the mounting hardware 230 instead. For example, if after determining the available screen space and placement of the other elements with respect to the mounts 200 to hold those elements in place (per block 630 and block 640) the system determines that one or more of the mounts 200 would extend past a mounting area of a display device 154, the system may update which mounting hardware option to use.

At block 650, the fabrication system 150 displays the (partial) schematic across the available screen space, with the portions of the canvas 590 not aligned with the screen space omitted from display based on the available screen real estate and spacing between display devices 154. The lengths of the cables 110 in the schematic 500 corresponding to non-displayed regions 520 are accounted for based on the associated gap distances between the display devices 154 and the non-displaying sections (e.g., frames and margins) of those display devices 154 so that the overall spacing of elements conforms to the scaling ratio selected for display of the schematic.

At block 660, the fabrication system 150 identifies additional elements to omit from display on the display devices 154. In various embodiments, the fabrication system 150 may use an AI module to identify, from data gathered during previous manufacturing and test operations, an optimized sequence to display the information contained in the schematic 500 to a fabricator. For example, the fabrication system 150 may display where the place the fixtures 160 before displaying where to place the cables 110 or may display where to place the elements of a first network 140a before displaying where to place the elements of a second network 140b. In various embodiments, the AI module may determine which presentation sequences for the elements from the schematic are more optimal than other presentation sequences based on a speed of assembly (faster being more optimal), test failure rate (lower being more optimal), scrap rate (lower being more optimal), or combinations thereof.

In some embodiments, the fabrication system 150 may use the output of the test devices 156 to identify a section of cable 110 to omit from display so as to highlight sections of cable associated with a fault or non-conformance during test so that the fabricator may repair, replace, or investigate a suspected sources of the fault or non-conformance more readily.

In various embodiments, method 600 may return to block 650 from block 660 in response to a command to advance a sequence for partial display of the schematic elements or to display test results from an in-site test of the article being manufactured according to the schematic so that a different subset of cables 110 and other elements are displayed to the fabricator. Accordingly, the fabricator may be presented with a relevant subset of information about the schematic so to decrease an error rate in fabrication, improve a speed of fabrication, or improve a speed of troubleshooting among other benefits.

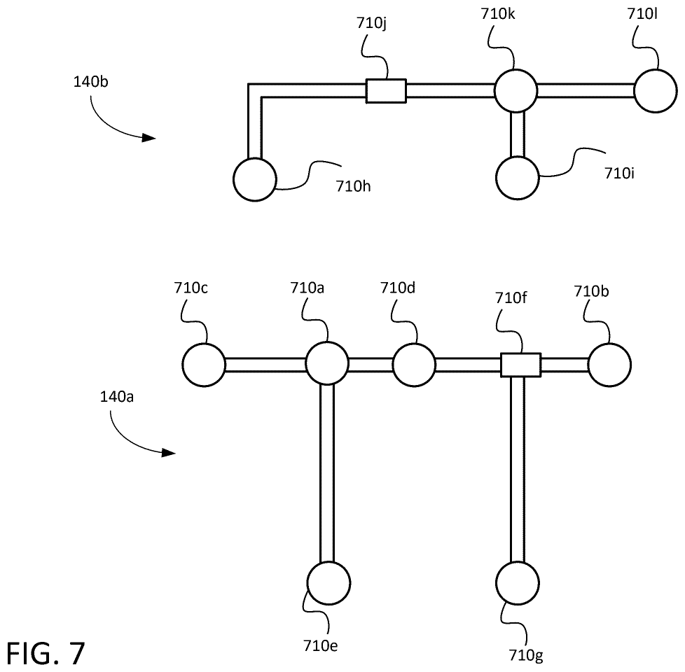

FIG. 7 illustrates networks 140 within an example wire harness 100 under test, according to embodiments of the present disclosure. Generally, point-to-point testing is used to determine that all of the connections and signaling pathways in a wire harness 100 are formed to specification, but this process is time consuming, especially as the number of connections grows, and creates difficulties when a change or update to the design occurs that alters one or more connections. Additionally, point-to-point testing may generate false positive or false negative test results due to overlapping tolerances and routing errors in a fabricated wire harness 100. However, by testing on a network basis, the overall speed of test may be improved, and a more detailed point-by-point analysis may be performed in the event of a failed test.

For example, by energizing the first node 710a of a plurality of nodes 710a-f (generally or collectively, nodes 710) in the first network 140a shown in FIG. 7, the test system can see that all of the other nodes 710b-d receive the signal from the first node 710a, and may conclude the entire first network 140a has been properly assembled. However, when the first node 710a has failed open (e.g., was not connected properly), the test system reports a missing voltage on the all of the other nodes 710b-gc1 of the first network 140a-leaving the source of the failure unknowable without further readings. In response to this failure, the test system then may switch to a point-to-point mode of analysis to narrow down the source of the failure. The nodes 710 described with respect to the networks 140a-b shown in FIG. 7 generally relate to splices 120 and connectors 130.

TABLE 1
Point-to-Point Test Example

| From Node | To Node | Continuity |
|---|---|---|
| Node3 | Node1 | FAIL |
| Node2 | Node6 | PASS |
| Node1 | Node5 | FAIL |
| Node1 | Node4 | FAIL |
| Node4 | Node6 | PASS |
| Node7 | Node6 | PASS |

Accordingly, the individual connections that failed may be checked, or the common element or node may be identified so that all of the failed connections may be checked in a single corrective action (e.g., replacing the connector at the first node 710a).

As will be appreciated, because the nodes 710 of the individual networks 140a-b are not in communication with one another across the different networks, a determination to perform a point-to-point test in the first network 140a does not trigger a point-to-point test among nodes 710h-7101 in the second network 140b.

In various embodiments, various AI modules may be used to identify the nodes 710 to use as signal sources to verify signal transmission in a given network 140 or narrow down a source of a fault using a minimal number of tests. For example, in the first network 140a, an AI module may identify that node 710d ais n communication with each other node 710 using the minimum number of hops/connections through other nodes 710. Accordingly, if fault exists in the cable 110 between node 710a and node 710d, a signal generated at node 710d would be received at nodes 710b, 710f and 710g, but not nodes 710a, 710c, 710e. In response to detecting the lack of signal reception at some of the node 710, the AI module may then identify node 710a as having the lowest number of hops/connections among the non-connected nodes 710 and the previously attempted signal source node 710d. Running a subsequent network test using node 710a as the signal source would identify that the signal is received by node 710c and node 710e, but no other node 710—indicating between the two network broadcast tests that the fault lies somewhere between node 710a and node 710d. Accordingly, the system minimizes the number of network broadcast tests needed to narrow down a location of a fault by sequentially selecting the nodes 710 with the lowest hop-distance to any nodes 710 not yet communicated with, and may avoid the need to perform point-to-point tests entirely.

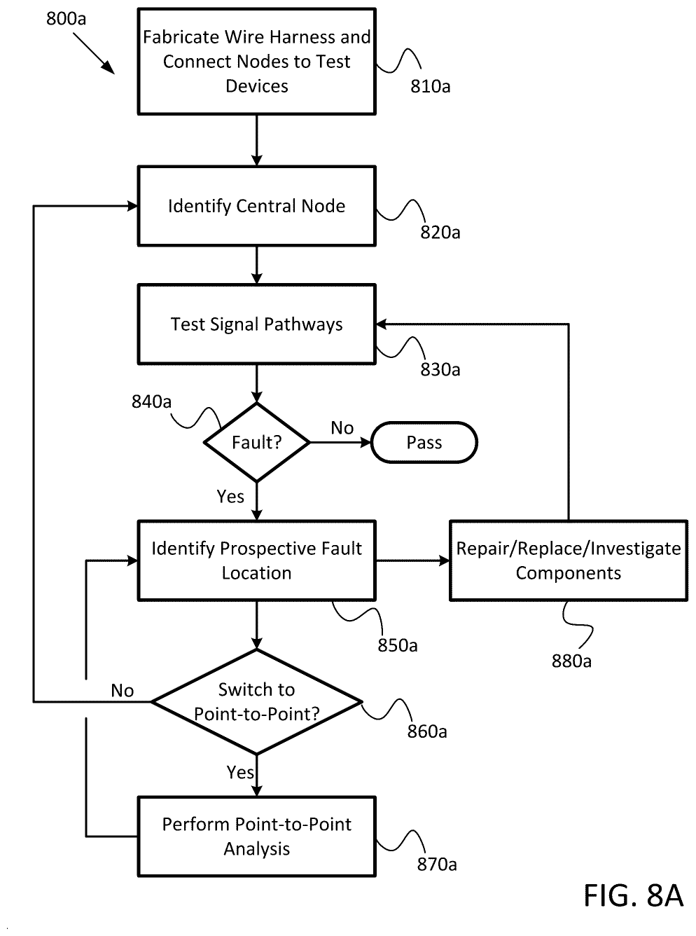

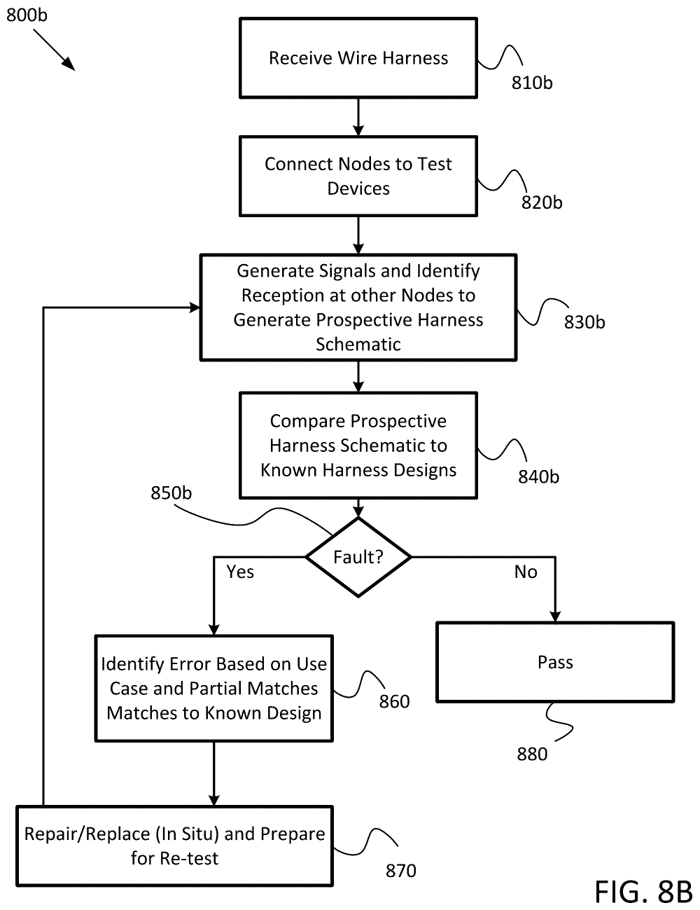

FIG. 8A is a flowchart of an example method 800a of testing a wire harness 100 using AI modules, according to embodiments of the present disclosure.

At block 810a, a fabricator fabricates a wire harness 100 using a fabrication system 150 to build the wire harness 100 according to a schematic, attaching various nodes 710 of the wire harness 100 to test devices 156 during fabrication.

At block 820a, the fabrication system 150 identifies a central node 710 for a given network 140 of the wire harness 100 to test. The central node 710 is the node 710 with the minimum number of connections to any other node 710 in a given network 140 that has not yet been verified as receiving test signals as indicated in the schematic (e.g., receiving signals that should be received, not receiving signals that should not be received).

In various embodiments, the central node 710 may be identified based on a current stage of fabrication-such as when a network 140 has (nominally) been fully completed according to a schematic 500 or at a stage before the network 140 has been fully built out by the fabricator, such as after a predefined number of minutes have elapsed since a last test or fabrication began, a predefined number components have been connected, a predefined component has been connected, a shift change or break in the manufacturing environment has occurred, or the like. In various embodiments, the triggering events to perform a test before complete construction of a given network 140 may be determined via an AI module based on various heuristics to improve manufacturing speed, reduce fabrication errors, or more readily identify problematic parts or techniques in construction before an error can propagate or result in more work to solve.

When performing test during fabrication, after having performed a previous test and adding additional nodes 710 to the network 140, the previously tested nodes 710 may be treated as one node 710 for purposes of counting connections/hops and identifying a subsequent central node 710.

At block 830a, the test device 156 associated with the central node 710 identified per block 820b generates a broadcast signal to test signal pathways from the central node 710 to the other nodes 710 in the network 140 (as currently constructed).

At block 840a, the test devices 156 determine if any faults have been detected, such as when any nodes 710 that should have received the broadcast signal did not, or when any nodes 710 that should not have received the broad cast signal did. If no faults are detected, method 800a may conclude with a passing result for the harness 100. If a fault is detected, method 800a may proceed to block 850a.

At block 850a, the fabrication system 150 identifies a prospective fault location in the network 140. In various embodiments, the fault is directionally located based on the last known signal that was received (or not) as expected. As will be appreciated with a network broadcast test, multiple faults, or one fault with multiple manifestations, may be detected in one test, which may require additional tests to narrow down a root cause to identify a component (or components) where the fault can be localized to. Accordingly, method 800a may delay proceeding to block 880a to repair or replace any components at the location of the prospective fault until one or more subsequent tests are performed using a different broadcast source node or via a point-to-point analysis.

At block 860a, the fabrication system 150 determines whether to switch to a point-to-point mode of analysis. When the determination is made to use a point-to-point mode of analysis, method 800a proceeds to block 870a, where the test devices 156 test each of the nodes 710 that did not pass test to identify a prospective fault locations per block 850a. When the determination is made to not use a point-to-point mode of analysis, method 800a returns to block 820a, where a new central node 710 with a shortest connection/hop distance among the nodes 710 that did not pass test is identified to form the basis of a subsequent network broadcast test.

At block 880a, fabrication system 150 directs the fabricator to repair, replace, or investigate further the components at the location of the prospective fault. In various embodiments the fabrication system 150 may highlight the components in the displayed image of the display devices 154 to direct the fabricator to the prospective fault via animating, color changes, size changes, removing display of other elements, displaying written instructions, generating an audio alert, and combinations thereof. After the fabricator has completed the repair, replacement, or investigation, method 800a may return to block 830a to retest and verify that the operations was successful in curing the fault.

FIG. 8B is a flowchart of an example method 800b of testing a wire harness 100 of unknown configuration, according to embodiments of the present disclosure.

At block 810b, a service technician (e.g., using a field service vehicle or in a manufacturing environment) receives a wire harness 100 of unknown configuration. When in the field, the service technician may disconnect the wire harness 100 for any existing devices. The unknown configuration may be the result of the wire harness 100 having an unknown identity (e.g., the service technician does not initially know whether the wire harness 100 is of model A or of model B), or the service technician not knowing how to wire harness 100 according to a service procedure such that terminal A is connected at test unit A and terminal B is connected as test unit B (rather than vice versa).

At block 820b, the service technician connects the terminal nodes 710 (and one or more intermediate nodes 710) to one or more test devices 156. As will be appreciated, because the wire harness 100 is of an unknown configuration, the service technician can connect the terminal nodes 710 in any order to any corresponding test devices 156. Accordingly, the efficiency of a service technician can be improved according to method 800b relative to methods that use prescriptive connections because the service technician can quickly connect the various terminals of the wire harness 100 of unknown configuration in any arrangement to the test devices 156 to receive an accurate identification of the wire harness 100 and the performance characteristics thereof.

At block 830b, the test devices 156 generate electrical or optical signals that are received by various other test devices 156 (or ports in the same test device 156). The ports/test devices 156 that receive the generated signals identify when a signal is received and the characteristics of that signal relative to the generated state of the signal (e.g., to identify any degradation, modulation, or other effects imparted by the cables 110 and intervening components), which the test devices 156 use to generate a prospective harness schematic. In various embodiments, the test devices 156 perform a point-to-point analysis of the various nodes 710, which may be unidirectional or bi-directional to account for one-way gatings or diodes in the cables 110 (e.g., from node A to node B or both from node A to node B and from node B to node A).

At block 840b, the service technician compares the output prospective harness schematic from block 830 to one or more known harness designs to identify what designs the unknown harness 100 conforms to. In some embodiments, the service technician may identify the supposed known harness design for the wire harness 100 of unknown configuration. In various embodiments, when the prospective schematic does not directly match any known designs (e.g., due to a fault in the harness 100 that affects the signal pathways) and the nominal design for the wire harness 100 is not known beforehand, the service technician may use one or more AI modules to identify a likely match based on the components included in the harness 100, similarities in signal pathways to known harness designs to those shown in the unknown harness 100, use cases for the unknown harness, purchase orders from the owner of the unknown harness 100, and combinations thereof.

In various embodiments, the signal pathways may be tested according to various transmission media according to the type of cables/wires/hoses/tubes placed under test. For example, transmission may include sending electrical signals, optical signals, hydraulic pressure waves, fluid flow volumes, pneumatic pressure waves or the like via the associated cabling.

At block 850b, in response to detecting a fault in the unknown harness 100, method 800b proceeds to block 860b. Otherwise, if no fault is detected (e.g., the unknown harness 100 matches a known design and performs within nominal ranges for that design), method 800b proceeds to block 880b.

At block 860b, a repair system used by the service technician to run the test devices 156 identifies errors in the unknown harness 100 based on the use case and any partial matches to known designs used to indicate the fault. In various embodiments, when the test devices 156 are deployed with display devices 154, a fabrication system 150 or a similar control system 440 in a repair system may display some or all of the generated prospective schematic during repair operations to draw the service technician's attention to sources of potential errors.

At block 870b, the service technician may repair or replace the some or all of the components of the wire harness 100 based on the errors identified per block 860b. When in the field, these repairs and replacements may be performed in situ with the parts available to the service technician (and while the harness 100 is still connected to some or all of the test devices 156). In various embodiments, one or more AI modules identify replacement parts that the service technician can use in the repair and replacement, which may be different from those initially installed, either due to an original mis-installation during fabrication or an earlier repair, or having different parts on hand for repair/replacement than were available before.

Method 800b returns to block 830b from block 870b to re-test the unknown harness 100 after repairs and replacements have been made. In various embodiments, the test routines in a re-test may omit testing any networks 140 that passed an earlier test, or may perform a network test (rather than a point-to-point test) to confirm that the repairs had no negative effects on that previously-passing network 140.

At block 880b, the unknown harness 100 passes test according to a known harness design, and may be reinstalled or replaced by a new harness 100 of an alternative design.

FIG. 9 illustrates an example computing environment 900 in which AI modules are deployed to aid in wire harness design, manufacture, and test, according to embodiments of the present disclosure. AI modules may be applied in engineering (e.g., to produce or optimize drawings and manufacturing instructions) and in metrics/decision making.

In one example, an AI routing module 910 may ingest raw data of “to lists”, connector part numbers, or other fabrication input data 920 to generate a ready-to-print or output schematic or schematic 500. As will be appreciated, a human user may adjust the output and set additional parameters for the generation and routing. Accordingly, once the connectors are placed, the AI routing module will draw the cables therebetween and place the hardpoints for connection to external devices or test devices 156 and fixtures 160 accordingly. The AI routing module may further make decisions such as wire gauge, terminal size, connector suitability, etc.

Additionally, the AI routing module 910 may learn from a cache of reference circuit designs 930 that include a description of the function of the circuits, parameters and values of the components of the circuits, or operational use cases. Then, using a design goal from the fabrication input data 920, and a learned understanding of circuit theory, the AI routing module 910 may then construct bills of material, wires, and interconnections thereof to achieve the design goal as part of the output schematics 500. The AI routing module 910 may automatically generate a schematic 500 and harness drawings with associated test parameters for ensuring fabrication to the build plan set forth in the schematic 500. Additionally, in the AI routing module 910 may operate in reverse—by receiving a schematic for a wiring diagram as part or all of the fabrication input data 920 and deducing the intent and functionality therein to establish a test procedure or an optimized design.

In various embodiments, the AI routing module 910 may be in communication with a natural language model 940 to accept inputs of natural language requirements for design. For example, an input of “Create a harness with two connectors, the first having three terminals and is waterproof. The second containing four terminals and is keyed so it can only be inserted one way around. Place two wires of two meters length between the terminals. Ensure that the unused terminal on the second connector is that nearest the keyway” and produce a schematic matching the requested features. These features may be translated to various computer aided drafting (CAD) programs using various formats expected by those programs, and the AI routing module 910 may freely translate between the different formats used by different programs.

In some embodiments, one or more of the routing module 910 and the natural language model 940 are in communication with an external interpretation model 945 for interpreting data from other systems. For example, the external interpretation model 945 may be a machine learning or artificial intelligence module that translates unstructured data or data structured according to other formats than those used by the routing module 910 into a format used by the routing module 910, and may be in communication with various other data sources such as computer aided drafting (CAD) systems or files, portable document format (PDF) files, extensible markup language (XML) files, or the like.

In one example, an AI component module 915 may ingest data of a parts database 950, component pricing, and component availability/order lead times, and designs of previously fabricated wire harnesses (and demand therefore) to identity optimal components or acceptable substitute components in the event of an inventory shortage for a given job. The AI component module 915 may interact with a designer to further clarify what qualifies as an optimal or acceptable component. For example when requesting the least expensive four-pin automotive rated connector for a design, and the AI component module 915 will return a selection, but may note that weather scaled connectors are more expensive than non-weather sealed connectors, and query the designer or offer a suggestion to the designer to see if weather sealing is a requirement in the design. Similarly, the AI component module 915 may infer some of answer by looking for clues in the design itself, such as the project title, the description of the connector, description of the wire, any sheet labels etc., or learning from previous designer responses.

Additionally, the AI component module 915 may provide proactive behaviors during a design process such as pop-up suggestions, enhanced manufacturing reports, and even global functions to refactor an entire design (possibly into a new revision), but with all enhanced decisions made. In some embodiments, the AI component module 915 may optimize the designs for manufacture, using note only the bill of material, the AI component module 915 may consider the build and test equipment available to the manufacturing environment. Accordingly, the AI component module 915 (and the routing module 910) may be in communication with a test data database 960 and a manufacturing data database 970 to identify various metrics related to the test and manufacture of the designs for wiring harnesses 100. Accordingly, the AI component module 915 may further optimize a bill of materials that from an engineering perspective appears to be optimized for various parameters, but in practice is not optimized for those parameters when accounting for human error, device fail rates, and the like once manufacturing is taken into account. For example, reductions build complexity, increases in speed of manufacturing, using a more robust part, etc. may all provide a more optimal design for a wire harness 100 that will have a long life in the field that may be difficult to capture from a pure engineering perspective without considering the effects of manufacturing.

FIG. 10 illustrates a computing device 1000, as may be used design, test, and manufacture of wire harnesses 100, according to embodiments of the present disclosure. The computing device 1000 may include at least one processor 1010, a memory 1020, and a communication interface 1030.

The processor 1010 may be any processing unit capable of performing the operations and procedures described in the present disclosure. In various embodiments, the processor 1010 can represent a single processor, multiple processors, a processor with multiple cores, and combinations thereof.

The memory 1020 is an apparatus that may be either volatile or non-volatile memory and may include RAM, flash, cache, disk drives, and other computer readable memory storage devices. Although shown as a single entity, the memory 1020 may be divided into different memory storage elements such as RAM and one or more hard disk drives. As used herein, the memory 1020 is an example of a device that includes computer-readable storage media, and is not to be interpreted as transmission media or signals per se.

As shown, the memory 1020 includes various instructions that are executable by the processor 1010 to provide an operating system 1022 to manage various features of the computing device 1000 and one or more programs 1024 to provide various functionalities to users of the computing device 1000, which include one or more of the features and functionalities described in the present disclosure, such as the control system 440. One of ordinary skill in the relevant art will recognize that different approaches can be taken in selecting or designing a program 1024 to perform the operations described herein, including choice of programming language, the operating system 1022 used by the computing device 1000, and the architecture of the processor 1010 and memory 1020. Accordingly, the person of ordinary skill in the relevant art will be able to select or design an appropriate program 1024 based on the details provided in the present disclosure. Additionally, the memory 1020 may store various schematics 500 (and sequences 510 thereof) for display to fabricators or modification by designers for use with the fabrication system 150 described herein.

The communication interface 1030 facilitates communications between the computing device 1000 and other devices, which may also be computing devices as described in relation to FIG. 10. In various embodiments, the communication interface 1030 includes antennas for wireless communications and various wired communication ports. The computing device 1000 may also include or be in communication, via the communication interface 1030, one or more input devices (e.g., a keyboard, mouse, pen, touch input device, etc.) and one or more output devices (e.g., a display, speakers, a printer, etc.).

Although not explicitly shown in FIG. 10, it should be recognized that the computing device 1000 may be connected to one or more public and/or private networks via appropriate network connections via the communication interface 1030. It will also be recognized that software instructions may also be loaded into a non-transitory computer readable medium, such as the memory 1020, from an appropriate storage medium or via wired or wireless means.

Accordingly, the computing device 1000 is an example of a system that includes a processor 1010 and a memory 1020 that includes instructions that (when executed by the processor 1010) perform various embodiments of the present disclosure. Similarly, the memory 1020 is an apparatus that includes instructions that, when executed by a processor 1010, perform various embodiments of the present disclosure.

FIG. 11 illustrates an example display device 154 and sections thereof, according to embodiments of the present disclosure. The display device 154 includes a screen 1110 on which images may be dynamically displayed and a frame 1120 (or margin) that surrounds the screen 1110 on which no images may be dynamically displayed by the display device 154. The overall physical dimensions of the display device 154 are given with a physical width (Wp) and physical length (Lp), which is defined by the outer dimensions of the frame 1220. The physical dimensions of the display space, in which dynamic images may be displayed by the display device 154, are defined by a display width (Wd) and display length (Ld), which may be used to calculate an aspect ratio of the display device 154 (e.g., Wd:Ld).

In addition to the physical dimensions and display dimensions of the display device 154, the display device 154 may also define a fixture space having fixture width (Wf) and a fixture length (Lf) defining a space in which fixtures 160 may be affixed to the screen 1110. Depending on the mounting hardware 230 used by the fixtures and the footprint of the feet 210 of the fixtures 160 available for use, the fixture space may change in dimensions. For example, when using tri-footed fixtures 160 using three suction cups 234, the fixture space may be smaller than using single-footed fixtures 160 using one suction cup 234 due to the greater space requirements of the tri-footed fixture 160 to securely bond to the surface of the screen 1110 relative to the single-footed fixtures 160. Similarly, when using fixtures 160 mountable via viscoelastic strips 232, the fixture space may be larger than when using fixtures mountable via suction cups 234 due to the reduced surface area needed to bond with the adhesive versus establish a vacuum seal via a suction cup 234.

FIGS. 12A-12E illustrate example display device positioning systems 1200a-b, according to embodiments of the present disclosure. When arranging multiple display devices 154, a fabricator may manually select and position the display devices 154 to permit multi-monitor display of a schematic 500 according to a scaling factor that considers any gaps in display (e.g., non-displayed regions) due to separation between the display devices 154. Similar, a control system 440 may automatically select (via programmed logic or user commands) and position (via associated motors, hydraulics, pneumatics, or the like) multiple display devices 154 to permit multi-monitor display of a schematic 500. Although a given number of elements are shown in the positioning system 1200, the present disclosure contemplates that a positioning system 1200 may include any number of elements for interacting with any number of display devices 154.

In FIG. 12A, a positioning system 1200a includes a plurality of armatures 1210a-c (generally or collectively, armature 1210) that are connected to frames 1220a-b (generally or collectively, frames 1220) via associated riders 1230a-c (generally or collectively, riders 230). The riders 230 permit movement of the associated armature 1210 in direction defined by the frame 1220 to which the rider 1230 is attached (e.g., the Z direction as illustrated). In some embodiments, the rider 1230 also permits rotation about the attached frame 1220, thereby allowing a display device 154 attached to the associated armature 1210 to be rotated into or out of position with other display devices 154 for use as part of a multi-display system.

Each armature 1210 includes one or more arms 1212 connected via one or more joints 1214 that may permit movement in one or more directions (e.g., rotation via hinges, movement in six degrees of freedom via ball-and-socket joints, etc.) of the connected elements. Each armature 1210 in connected on a first end to a rider 1230 and on a second end (opposite to the first end) terminates with a display mount 1240 that is configured to secure a display device 154 thereto.

In FIG. 12B, a positioning system 1200b includes a plurality of tracks 1250a-b (generally or collectively, tracks 1250) secured to pairs of frames 1220a-d. Each track 1250 is able to move in a first direction along the frames 1220 (e.g., the Z direction), and allows an associated display mount 1240 to move in a second direction (e.g., the X direction). Each of the tracks 1250 is located at a different depth (e.g., in the Y direction) in the system 1200b to permit individual movement of the display mounts 1240 so as to not interfere with each other's movement, which may place the display devices 154 at different depths, or employ the use of one or more risers 1260 or lift mechanisms that permit movement in the height/depth direction (e.g., in the Y direction), or the use of mounts 200 with different lengths of necks 240.

In some embodiments, as shown in FIG. 12C, a clear acrylic (or other transparent material) screen 1270 is placed over the positioning system 1200 in a constant plane, and the display devices 154 may be moved at various distances relative to the screen to allow a fabricator to place the fixtures 160 thereon. The screen may include peg holes or be free of through-holes in a mounting area thereof. The screen 1270 may also act as a safety barrier-preventing a fabricator from being entangled with the mechanisms of the positioning system 1200 during operation (e.g., automated movement thereof). Accordingly, the positioning system 1200 may also repurpose display devices 154 during fabrication; automatically moving a first dynamic display 410a from a first position to a second position after the fabricator has placed the indicated components to display a new set of components without requiring the use of additional subsequent dynamic displays 410.

For example, rather than including a third dynamic display 410c, the positioning system 1200 may display a first portion of a schematic 500 on a first dynamic display 410a and a second portion of the schematic 500 on a second dynamic display 410b at a first time. After the elements have been added to the screen 1270, at a second time, the positioning system 1200 may move the first dynamic display 410a to a third position relative to the second dynamic display 410b. At the second time, the first dynamic display 410a displays a third portion of the schematic 500, while the second dynamic display 410b may display the second portion of the schematic 500 or (if also moved) a fourth portion of the schematic 500.

The positioning systems 1200 hold the display devices in place via static forces in the mechanisms thereof so that a fabricator may reliably position, and leave positioned, multiple display devices 154 for use in fabricating an article of manufacture. In some embodiments, one or more of the display devices 154 may be held in a constant or static position by the positioning system 1200, with the other display devices 154 being moved relative thereto (e.g., omitting motor or other automated or manual devices for the movement of one or more display devices 154).

FIG. 12D illustrates a positioning system 1200 includes a frame 1220, on which several groups of ports 1280 are disposed. The ports 1280 may include various hook-ups or connections for the test of an article of manufacture, such as a wire harness 100 so that the cables 110 or connectors 130 may be connected to test devices 156 or external sources 1290 via port cables 1285 or via the cables 110. These external sources 1290 may include fluid or air sources (including pumps and reservoirs) for use by the test devices 156 for testing one or more of any hydraulic, fluid delivery, or pneumatic cables included in the wire harness 100. These external sources 1290 may include electrical power sources, electrical signal generators, or optical signal generators use by the test devices 156 for testing one or more of any electrical or optical cables included in the wire harness 100. In various embodiments, the control system 440 manages the provision of test signals, fluid flow, pressure, etc. applied from the external sources 1290. In various embodiments, the test devices 156 may be in communication with various sensors, switches, valves, or other control and measurement devices 1295 disposed or in communication with the various connectors 130, cables 110, or other elements of the harness 100.

As illustrated, the positioning system 1200d in FIG. 12D includes a transparent screen 1270 that the fixtures (160) and various elements of the wire harness 100 are disposed on a first side of and the dynamic displays 410a-b are disposed on a second (opposite) side of, to display the schematic of the wire harness through the transparent screen 1270 to an operator. Accordingly, various fixtures (160) and installed elements of a wire harness 100 may remain in place during fabrication, while the dynamic displays 410 are permitted to move to new positions for the installation of different fixtures (160) and elements of the wire harness 100. For example, a first dynamic display 410a may initially be disposed at a first position for the installation of a first connector 130a and the associated cables 110 and port cables 1485 (e.g., displaying a first portion of the schematic), and after fabrication for this sub-element is complete, the first dynamic display 410a is moved to a second position for installation of a second connector 130b and the associated cables 110 and port cables 1485 (e.g., displaying a second portion of the schematic).

FIG. 12E illustrates a positioning system 1200c that includes a combined test device 156 and control system 440 that is mounted to the frame 1220 of the positioning system 1200c, and includes the ports 1280 to which various cables 110 and port cables 1285 are connected. In various embodiments, the combined test device 156 and control system 440 may include a touch screen or other interface to received commands from and convey instructions to a fabricator.

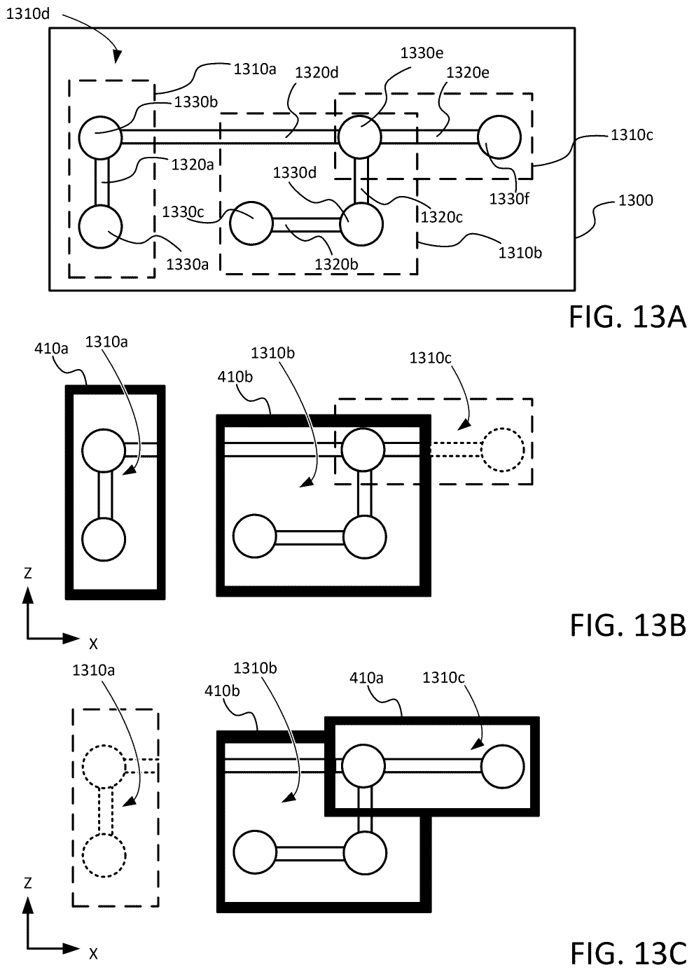

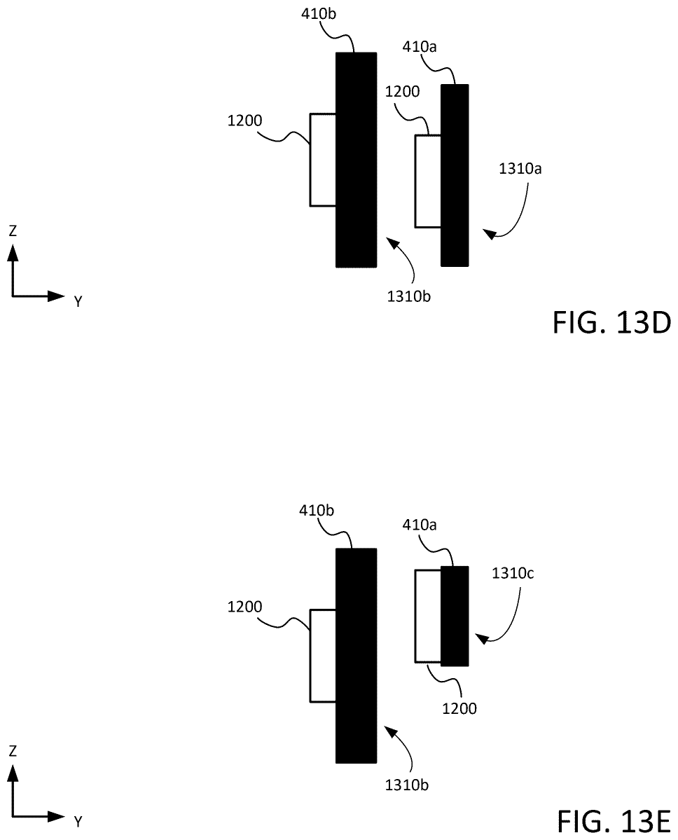

FIGS. 13A-13E illustrate an example use case of dynamic displays 410, according to embodiments of the present disclosure. FIG. 13A illustrates a schematic 1300 of an article of manufacture, such as a wire harness 100. As shown, the schematic 1300 includes various cable elements 1320a-c (generally or collectively cable elements 1320) and non-cable elements 1330a-f (generally or collectively non-cable elements 1330), and is divided into four portions 1310a-d (generally or collectively, portions 1310) for display on one or more dynamic display devices 410 based on the position of the dynamic displays relative to a reference point in the physical environment to which the schematic 1300 is mapped. Accordingly, as shown in FIG. 13B, a first dynamic display device 410a is positioned for displaying the first portion 1310a and a second dynamic display device 410b is positioned for displaying the second portion 1310b. However, not all of the third portion 1310c is aligned with a dynamic display device 410 in FIG. 13B. Accordingly, an operator or positioning system (1200) may move the first dynamic display device 410a from a first position to a new (e.g., third) position so that the third portion 1310c of the schematic 1300 may be displayed on a dynamic display device 410 that previous displayed a different portion 1310 of the schematic 1300, such as the first dynamic display device 410a showing the third portion 1310c of the schematic 1300 in FIG. 13C.

In various embodiments, a remainder (e.g., fourth) portion 1300d of the schematic 1300 may include parts of the schematic that do not indicate elements of the article of manufacture (e.g., blank spaces, notes, parts lists, keys, engineering signoffs, etc.) or only cable elements 1320 of the article of manufacture. As will be understood, the cable elements 1320 may include electrical wires, optical cables, hydraulic or pneumatic tubing or ducts, flowing liquid hoses, and the like, whereas the non-cable elements 1330 may include any element of the manufacture that is not described as a cable element 1320.

In various embodiments, the positioning system (1200) may move one or more dynamic display devices 410 to new positions to display different portions 1310 of the schematic 1300 in response to receiving a signal indicating that the elements of the article of manufacture in the previous portions have been assembled. For example, after installing the elements of a wire harness shown in the first portion 1310a of a schematic 1300 by a first dynamic display device 410a, and operator may signal to a positioning system (1200) that the first dynamic display 410a is to be moved to a third position associated with display of the third portion 1310c of the schematic, to which the positioning system (1200) responds by moving the first dynamic display device 410a and updating what portion 1310 of the schematic 1300 is displayed by the first dynamic display device 410a.

As illustrated in FIGS. 13B-13E, a segments of the second portion 1310b and the third portion 1310c overlap with one another, such that both the second portion 1310b and the third portion 1310c share elements with one another (e.g., given element of the article of manufacture indicated in the schematic 1300 appears in two or more portions 1310 into which the schematic 1300 is divided). FIGS. 13B and 13D correspond to a view of the dynamic display devices 410 in a first configuration to show the first portion 1310a and the second portion 1310b of the schematic 1300, while FIGS. 13C and 13E correspond to a view of the dynamic display devices 410 in a second configuration to show the third portion 1310c and the second portion 1310b of the schematic 1300. Accordingly, when the first dynamic display device 410a is positioned to overlap the second dynamic display device 410b when viewed in a first plane (e.g., as in FIG. 13C) when viewed in a second plane (e.g., as in FIG. 13E), the dynamic display devices 410a may remain offset and out of contact with one another.

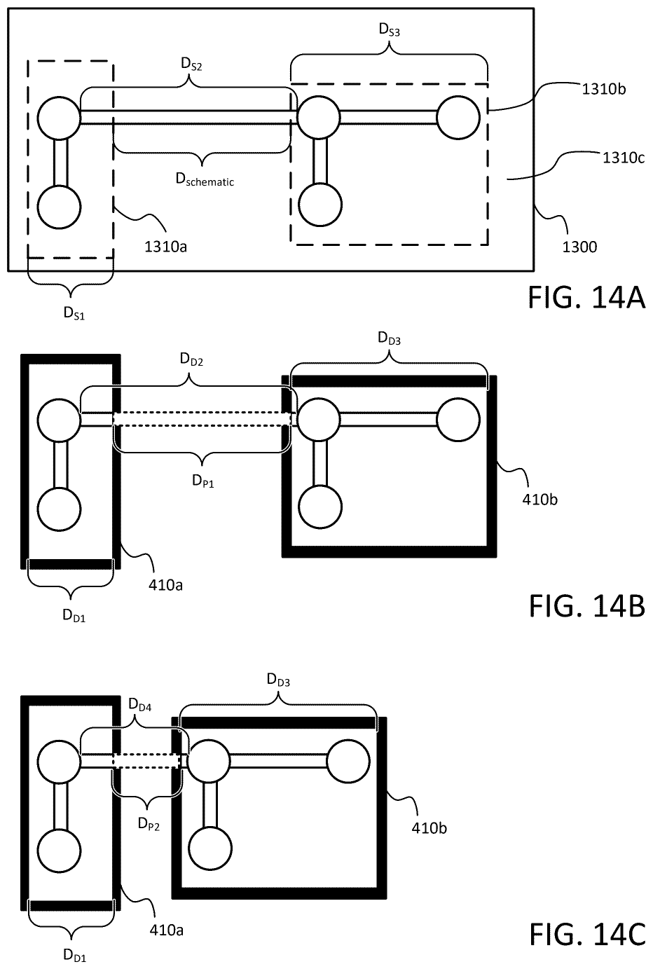

FIGS. 14A-14C illustrate an example use case of dynamic displays 410, according to embodiments of the present disclosure. FIG. 14A illustrates a schematic 1300 of an article of manufacture, such as a wire harness. As shown, the schematic 1300 is divided into three portions 1310a-c for display on one or more dynamic display devices 410 based on the position of the dynamic displays 410 relative to a reference point in the physical environment to which the schematic 1300 is mapped.

As shown in FIG. 14A, within the schematic 1300, the width of the first portion 1310a is of a first schematic distance (D_{S1}), the width of a cable between elements in the first portion 1310a and the second portion 1310b is of a second schematic distance (D_{S2}), the width of the second portion 1310b is a third schematic distance (D_{S3}), and the width between the first portion 1310a and the second portion 1310b is an interspace schematic distance (D_{Schematic}).

FIG. 14B illustrates display of the first portion 1310a on a first dynamic display device 410a and display of the second portion 1310b on a second dynamic display device 410b. As illustrated on the dynamic display devices 410, the width of the first portion 1310a is of a first display distance (D_{D1}), the width of a cable between elements in the first portion 1310a and the second portion 1310b is of a second display distance (D_{D2}), the width of the second portion 1310b is a third display distance (D_{D3}), and the width between the first portion 1310a and the second portion 1310b is a first physical distance (D_{P1}). In various embodiments, the ratio of the display distances relative to the schematic distances is set according to a scaling factor, and the display on the display device 410 is generally about 1:1 with respect to the physical elements of the article of manufacture that is assembled according to the displayed portions of the schematic 1300.

FIG. 14C illustrates display of the first portion 1310a on a first dynamic display device 410a and display of the second portion 1310b on a second dynamic display device 410b. As illustrated on the dynamic display devices 410, the width of the first portion 1310a is of a first display distance (D_{D1}), the width of a cable between elements in the first portion 1310a and the second portion 1310b is of a second display distance (D_{D2}), the width of the second portion 1310b is a third display distance (D_{D3}), and the width between the first portion 1310a and the second portion 1310b is a second physical distance (D_{P2}). In various embodiments, the schematic distance between two portions 1310 of the schematic 1300 may be equal to the physical distance between the displayed portions 1310 on the dynamic display device 410 (e.g., as in FIG. 14B), but the system may also compress the distances when cables or no other elements are present in the remainder portion between the two portions 1310 (e.g., as in FIG. 14C). Accordingly, when the remainder portion is disposed at least partially between a first portion 1310a and a second portion 1310b of the schematic 1300, a first scaling ratio may be used for displaying the first portion 1310a and the second portion 1310b, and a second scaling ratio may be applied to the remainder portion so that a physical distance (e.g., D_{P2}) between the first display surface and the second display surface is less than a schematic distance (e.g., D_{Schematic}) between the first portion and the second portion in the schematic 1300.

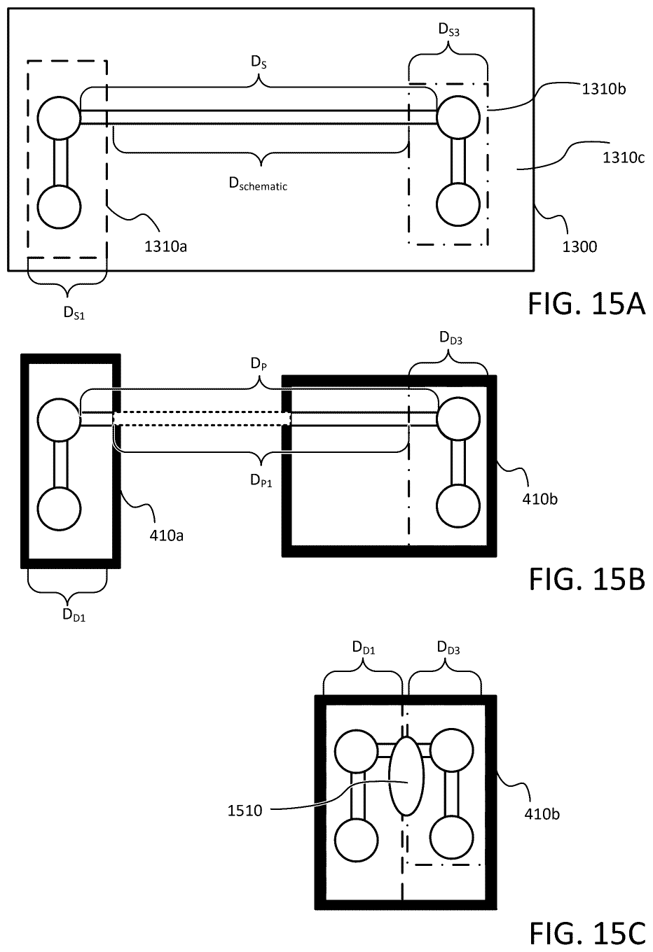

FIGS. 15A-15C illustrate an example use case of dynamic displays 410, according to embodiments of the present disclosure. FIG. 15A illustrates a schematic 1300 of an article of manufacture, such as a wire harness. As shown, the schematic 1300 is divided into three portions 1310a-c for display on one or more dynamic display devices 410 based on the position of the dynamic displays 410 relative to a reference point in the physical environment to which the schematic 1300 is mapped.

As shown in FIG. 15A, within the schematic 1300, the width of the first portion 1310a is of a first schematic distance (D_{S1}), the width of a cable between elements in the first portion 1310a and the second portion 1310b is of a second schematic distance (D_{S2}), the width of the second portion 1310b is a third schematic distance (D_{S3}), and the width between the first portion 1310a and the second portion 1310b is an interspace schematic distance (D_{Schematic}).

FIG. 15B illustrates display of the first portion 1310a on a first dynamic display device 410a and display of the second portion 1310b on a second dynamic display device 410b. As illustrated on the dynamic display devices 410, the width of the first portion 1310a is of a first display distance (D_{D1}), the width of a cable between elements in the first portion 1310a and the second portion 1310b is of a second display distance (D_{D2}), the width of the second portion 1310b is a third display distance (D_{D3}), and the width between the first portion 1310a and the second portion 1310b is a first physical distance (D_{P1}). In various embodiments, the ratio of the display distances relative to the schematic distances is set according to a scaling factor, and the display on the display device 410 is generally about 1:1 with respect to the physical elements of the article of manufacture that is assembled according to the displayed portions of the schematic 1300.

FIG. 15C illustrates display of the first portion 1310a and the second portion 1310b on the second dynamic display device 410b, thereby allowing the system to omit usage of the first display device 410a and to combine multiple portions 1310 for display on a single dynamic display device 410 when the dimensions of the portions 1310 are less than or equal to the dimensions of a display device 410. As illustrated, the second dynamic display device 410b includes an additional indicia 1510 to indicate the coiled or hanging cable element between the combined first and second portions 1310a-b.

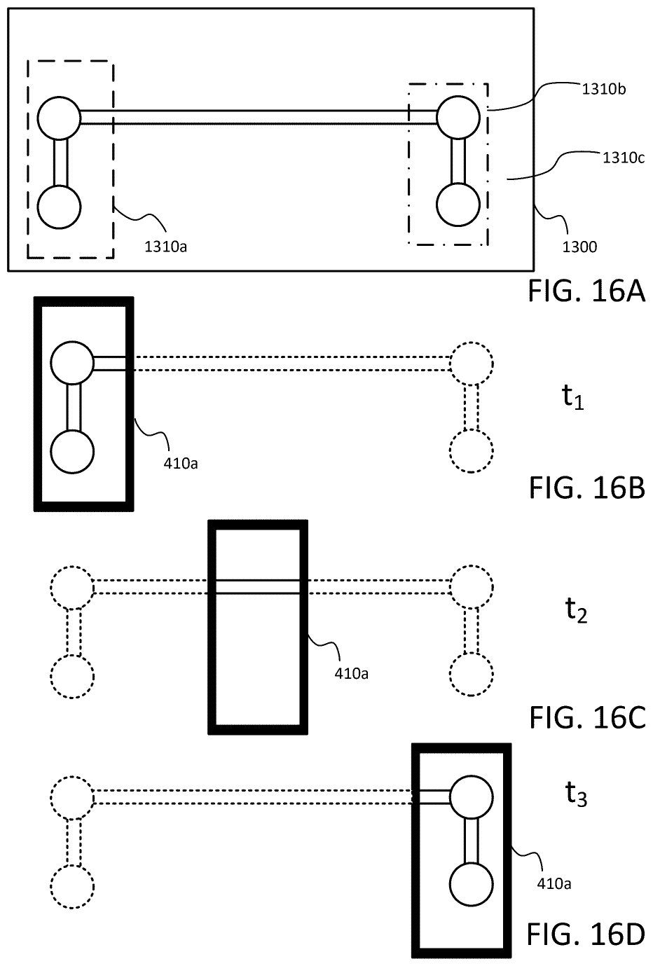

FIGS. 16A-16D illustrate an example use case of dynamic displays 410, according to embodiments of the present disclosure. FIG. 16A illustrates a schematic 1300 of an article of manufacture, such as a wire harness. As shown, the schematic 1300 is divided into three portions 1310a-c for display on one or more dynamic display devices 410 based on the position of the dynamic displays 410 relative to a reference point in the physical environment to which the schematic 1300 is mapped.

FIGS. 16B-16D illustrate movement of a first dynamic display 410a to different locations in an environment mapped to the schematic 1300. At a first time (t1), shown in FIG. 16B, the first dynamic display 410a, when positioned at a location associated with the first portion 1310a, the first display device 410a shows the first portion 1310a. At a second time (t2), shown in FIG. 16C, the first dynamic display 410a, when positioned at an intermediate location between locations associated with the first portion 1310a and the second portion 1310b, shows elements of the schematic 1300 (e.g., a section of cable) between the first portion 1310a and the second portion 1310b associated with the intermediate location in the schematic 1300. At a third time (t3), shown in FIG. 16D, the first dynamic display 410a, when positioned at a location associated with the second portion 1310b, the first display device 410a shows the second portion 1310b.

In various embodiments, the system may animate the display of the schematic as the display device 410 moves through the environment (and in FIGS. 16B-16D) to provide context or continuity to an operator (either moving the display device 410 manually or via an automated positioning system 1200). In some embodiments, the system may blank out the display, display instructions, or display a non-schematic image when the display device 410 is not positioned at a location associated with a displayable portion 1310a-b of the schematic (versus a remainder portion 1310c) to avoid inducing motion sickness, avoid confusing an operator with “subsequent operation” elements of the article of manufacture, or preserve privacy.

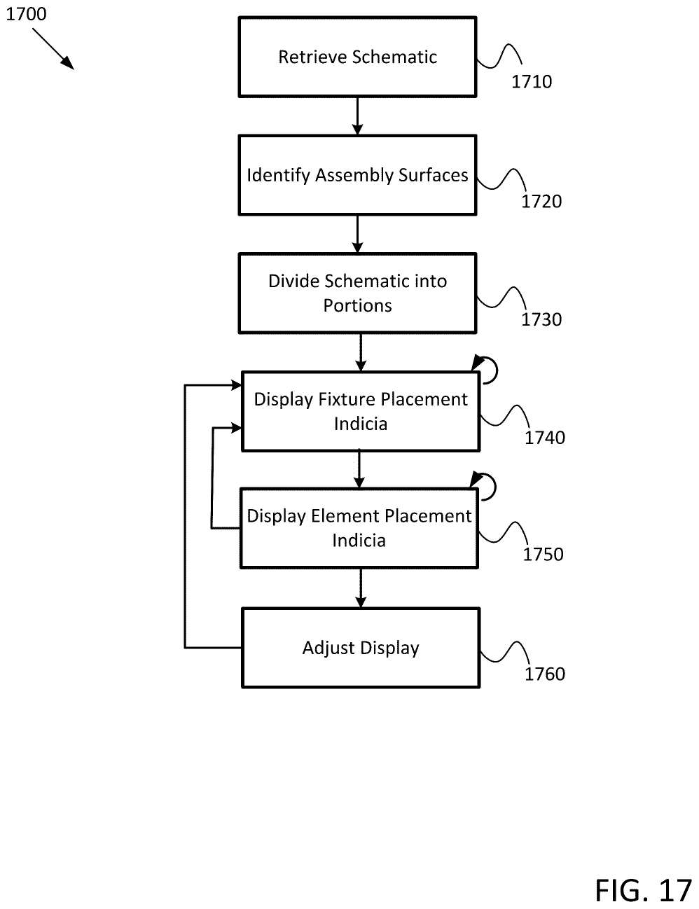

FIG. 17 is a flowchart for an example method 1700 of configuring the display of a schematic during fabrication of an article of manufacture, according to embodiments of the present disclosure. Method 1700 begins at block 1710 where the system retrieves a schematic of an article of manufacture, such as a wire harness, to display during manufacture of the article of manufacture. In various embodiments, the schematic may be stored and called from a local computer storage medium or retrieved via a remote connection (e.g., a network connection) from another device.

At block 1720, the system identifies a plurality of assembly surfaces on which to display the schematic. The schematic may be displayed according to various setting provided by a user, which may include a scaling ratio for the size of the displayed versions of elements of the article of manufacture relative to the size of physical versions of the elements of the article of manufacture. For example, when displaying an element a square of sides of length X, the system may use a 1:1 ratio to display a video or image of that element with sides of length X, but may use other ratios to increase or decrease the displayed size of the video or image of the element relative to the actual physical size of that element (e.g., to draw attention to the element, apply a grow/shrink animation effect, etc.).

In various embodiments, the assembly surfaces include one or more of projection surfaces associated with projectors (for use as the display devices), computer monitors, televisions, touch screen devices, and transparent screens that disposed between a display device and where a fabricator is located in the environment to view the schematic on the assembly surface. For example, the system may select a projection surface as a first assembly surface and the screen of a computer monitor as a second assembly surface. For example, the system may select the screen of a first computer monitor as a first assembly surface and the screen of a second computer monitor as a second assembly surface. Additionally, when displaying a schematic, various portions may be displayed contemporaneously with one another or sequentially to one another; accordingly, the system may select the screen of a first computer monitor as a first assembly surface and a third assembly surface and select the screen of a second computer monitor as a second assembly surface.

At block 1730, the system divides the schematic into a plurality of portions so that the schematic has at least a first portion including a first set of the elements of the article of manufacture, a second portion including a second set of the elements of the article of manufacture, and a remainder (e.g., third) portion including segments of the schematic in which the first set and the second set of elements are not included. For example, the remainder portion may include only cables or notes, engineering sign-offs, and metadata. The first and second portions are at least partially discontinuous with one another, but may include areas of overlap, where one or more elements in the first portion also appear in the second portion. Additionally, segments of the remainder portion may be interposed therebetween the first and second portions.

In various embodiments, the size, shape, and orientation of the (non-remainder) portions that the schematic is divided into are based on the scaling ratio, physical dimensions of the plurality of assembly surfaces or display devices available to display the portions, display spaces within the physical dimensions of the plurality of assembly surfaces configured for display of portions of the schematic; and fixture spaces within the display spaces of the plurality of assembly surface configured to selectively mount fixtures thereto for assembly of the article of manufacture. In various embodiments, an AI module or system may optimize the placement and division of portions of the schematic.

At block 1740, the system (optionally) displays fixture placement indicia associated with the assembly of the article of manufacture. In embodiments where a fabricator builds multiple instances of an article of manufacture after a single set up operation, the fabricator may leave the assembly fixtures in place between assembling different instances of the article of manufacture, and the system may omit displaying the fixture placement indicia (e.g., because the fixtures are already in place).

In various embodiments, display of the fixture placement indicia may include the display of notes or instructions associated with fixtures or elements or indica therefor in fabricating the article of manufacture; and animating display of various indicia.

A fabricator may send a command to the system once the fixtures are placed on the fixture placement indicia to advance method 1700 to the next operation and (optionally) remove display of the fixture placement indicia. In various embodiments, the next operation may repeat block 1740 (e.g., to display different fixture placement indicia) or proceed to block 1750. In various embodiments, the command may include pressure signals on a touch-sensitive assembly surface that indicate that the fixtures have been added onto the assembly surface, image recognition by a camera system observing the assembly surfaces for the present of the fixtures, or voice/manual command from an operator.

At block 1750, the system displays element placement indicia associated with the assembly of the article of manufacture. For example, the system may display the first portion of the schematic on a first assembly surface of the plurality of assembly surfaces and display the second portion of the schematic on a second surface of the plurality of assembly surfaces, contemporaneously to displaying the first portion of the schematic on the first assembly surface.

Because the assembly operation may include multiple operations, not all portions of the schematic may be displayed at the same time. For example, the display the display of the portions may include adjusting for a gap distance between the first assembly surface and the second assembly surface, wherein the gap distance account for a first margin of a first display device on which the first portion is displayed and a second margin of a second display device on which the second portion is displayed, and elements of the schematic that correspond to the gap distance arc not displayed, but the dimensions thereof are accounted for when positioning the assembly surfaces relative to one another. In some embodiments, the distances for both displayed and non-displayed portions are shown according to the same scaling ratio. In some embodiments, such as when a remainder portion is disposed at least partially between a first portion and a second portion of the schematic, the first portion and the second portion are displayed according to the scaling ratio, but a physical distance between the first display surface and the second display surface is less than a schematic distance between the first portion and the second portion. Stated differently, portions that do not include non-cable elements of the article of manufacture may be scaled according to a compressed scaling ratio to save space in the assembly area, reduce operator fatigue, and improve ergonomics or may be scaled according to an expanded scaling ratio to permit multiple fabricators to work on assembling different portions of the article of manufacture in different spaces from one another.

In various embodiments, display of the fixture placement indicia may include the display of notes or instructions associated with fixtures or elements or indica therefor in fabricating the article of manufacture; and animating display of various indicia. In various embodiments, the animation of the various indicia may include displaying a first subset of the indicia at a first time and a second subset of the indicia at a second time, which may be used to demonstrate an intended operational order for assembly.

A fabricator may send a command to the system once the elements are placed on the element placement indicia to conclude method 1700 (e.g., on completion of assembly of the article of manufacture) or advance method 1700 to the next operation and (optionally) remove display of the element indicia. In various embodiments, the next operation may repeat block 1750 (e.g., to display different element placement indicia), return to block 1740 (e.g., to display new fixture placement indicia), or proceed to block 1760. In various embodiments, the command may include pressure signals on a touch-sensitive assembly surface that indicate that the elements have been added onto the fixtures, image recognition by a camera system observing the assembly surfaces for the present of the elements, or voice/manual command from an operator.

At block 1760, the system adjusts display of the portions of the schematic. In various embodiments, an operator may be signaled (e.g., via instructions or notes on a display screen or assembly surface) to manually move a display device to a new position in the environment or a positioning system may automatically move where the display device is positioned to display the schematic (e.g., physically moving a display device or refocusing where a project displays an image). For example, when the schematic includes a portion including a new set of the elements of the article of manufacture that are not currently displayed, the system may move a first display device used to display a current portion of the schematic from a first location to a second location in an environment, wherein the first location is associated with display for the current portion and the second location is associated with display of the new portion.

In various embodiments, method 1700 may proceed from block 1760 to block 1740 (e.g., to display new fixture placement indicia), to block 1750 (e.g., to display new element placement indicia).

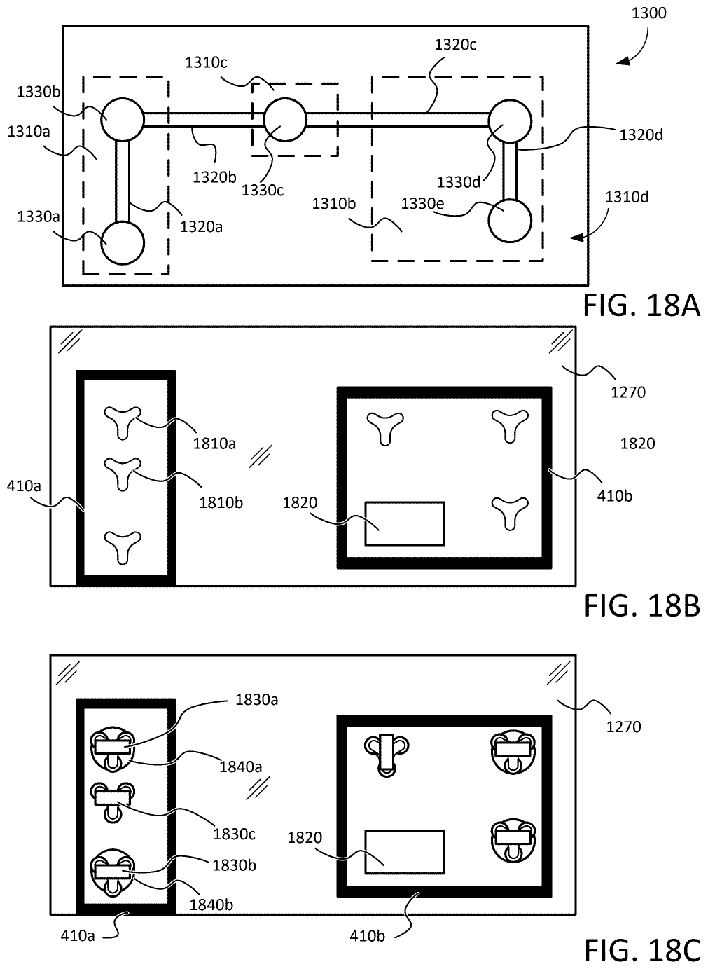

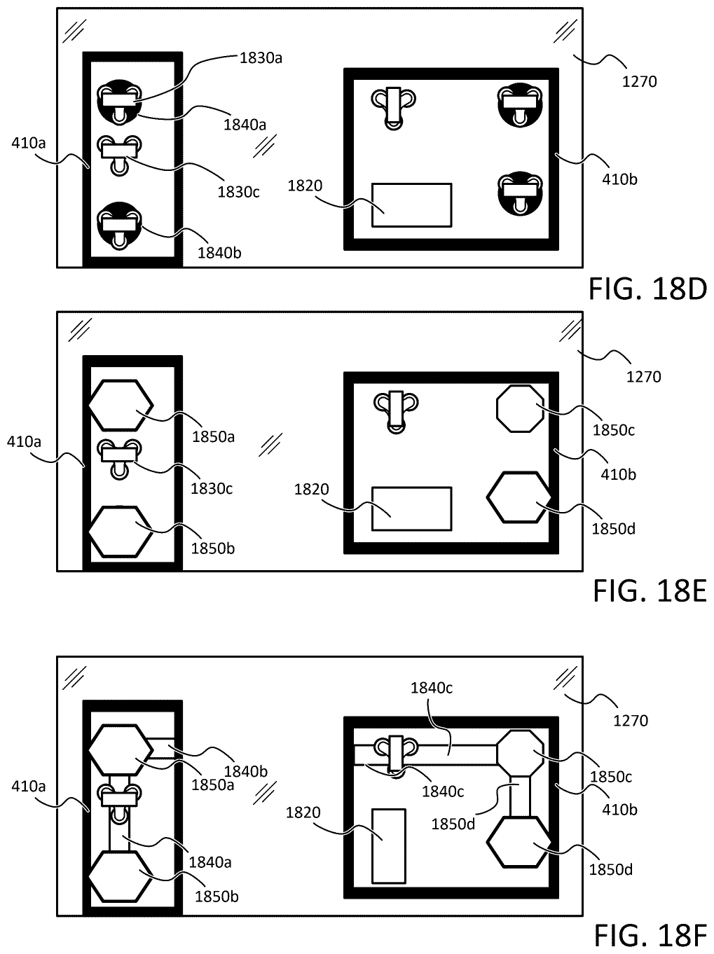

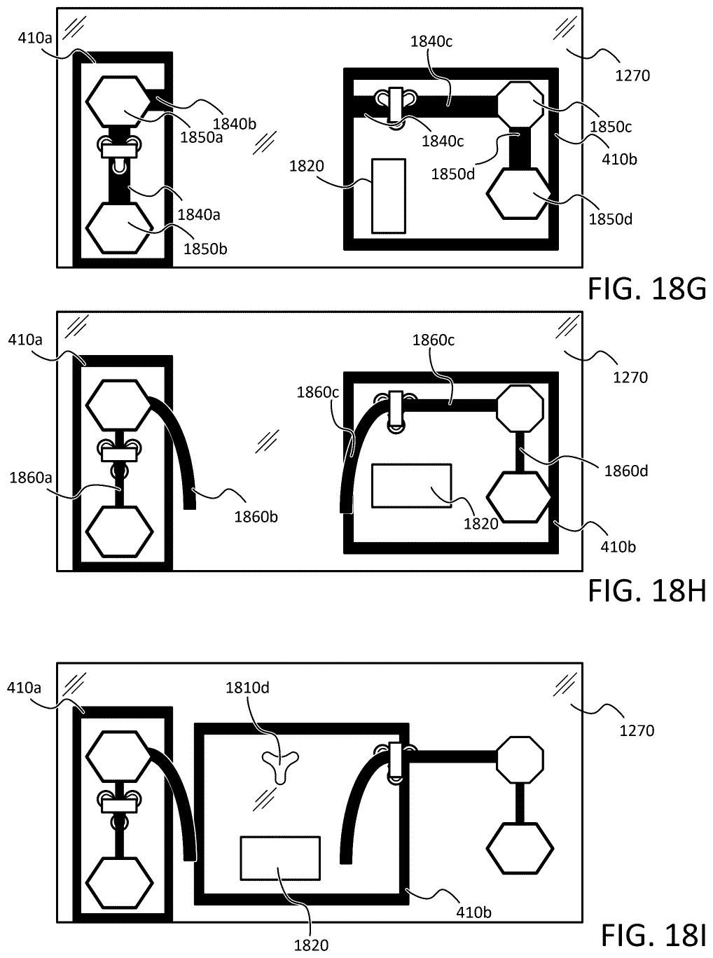

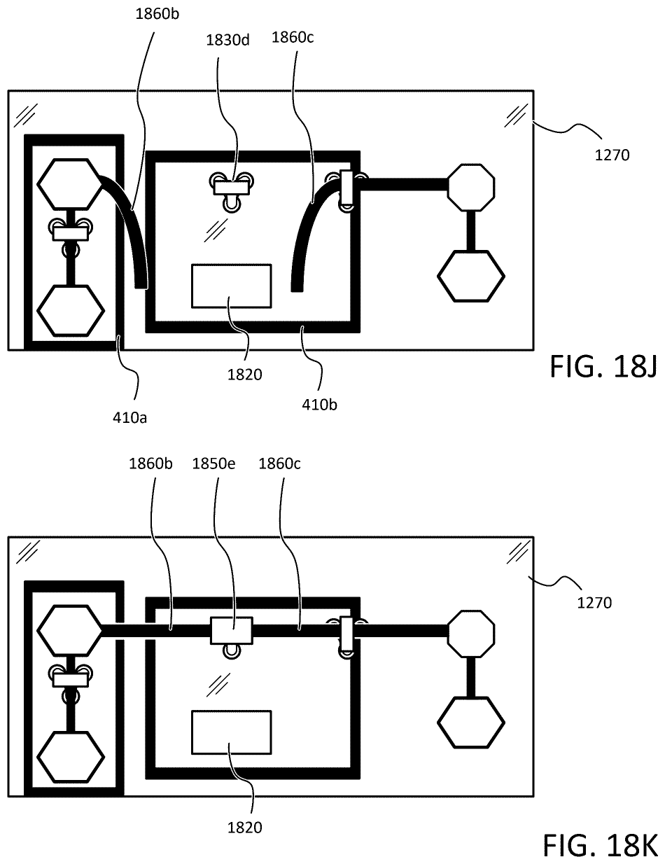

FIG. 18A-18K are example layouts of multiple display screens 410 during fabrication of an article of manufacture, according to embodiments of the present disclosure. FIG. 18A illustrates a schematic 1300 of an article of manufacture, such as a wire harness 100, that is divided into a plurality of portions 1310a-d, with various schematic representations of cable elements 1320 and non-cable elements 1330 therein.

As illustrated in FIGS. 18B-18K, a first display device 410a and a second display device 410b are positioned behind a transparent screen 1270, to allow for fixtures and elements of the article of manufacture to be secured in front of the transparent screen 1270. As will be appreciated, an projection surface may be used in addition or alternatively to a transparent screen 1270 so that projectors may be used as display devices that are focused on different portions of the projection surface similarly to how the dynamic display devices 410 are shown and discussed behind the transparent screen 1270.

In FIG. 18B, the display devices 410 display initial layouts for various fixture placement indicia 1810a-b (generally or collectively, fixture placement indicia 1810) that indicate where fixtures (e.g., the mounts 200 thereof) are to be placed for assembly of the article of manufacture indicated in the schematic 1300. Additionally, in some embodiments, one or more of the display devices 410 may display manufacturing notes 1820, which may identify various materials, instructions, time information, or the like to an operator. The manufacturing notes 1820 may include words, numbers, pictures, pictograms, videos (with or without associated audio), and combinations thereof, and may be updated and re-positioned (or omitted) at various times throughout the manufacturing process.

In FIG. 18C, several fixtures 1830a-c (generally or collectively, fixtures 1830) have been placed over the fixture placement indicia 1810, and the figure indicia 1810 may be removed from display (e.g., in response to a command from an operator to proceed to a next assembly operation) and replaced with element indicia 1840a-b (generally or collectively, element indicia 1840), new figure indicia 1810 or combinations thereof.

As will be appreciated when using display devices 410 behind an assembly surface 1270 to which the fixtures 1830 are attached, the element indicia 1840 may be fully or partially obscured by physical objects such as fixtures 1830 or the actual elements of the article of manufacture once assembled, accordingly, the system may impart an animation effect, color change, offset display, or other mechanism to identify to the operator where the elements should be installed. For example, FIG. 18D illustrates the element indicia 1840 using a different color than FIG. 18C, and the system may periodical oscillate between the states shown in FIGS. 18C and 18D to “flash” or “strobe” the locations of the element indicia 1840 to draw attention to the element indicia 1840.

Similarly, when using display devices 410 that project images onto a projection surface, the projected element indicia 1840 may overlay any physical objects such as fixtures 1830 or physical elements of the article of manufacture, and the system may use various mechanisms to draw operator attention to the element indicia 1840.

In FIG. 18E, the operator has installed various elements 1850a-d where the element indicia 1840 indicated in FIGS. 18C and 18D, and the display devices 410 may cease displaying the associated element indicia.

In FIGS. 18F and 18G, the display devices 410 display a set of element indicia 1840a-d for the next set of elements to be assembled into the article of manufacture, using various colors or animations to draw attention to the element indicia 1840.

In FIG. 18H, the operator has installed various elements 1850a-d where the element indicia 1840 indicated in FIGS. 18F and 18G, and the display devices 410 may cease displaying the associated element indicia. As will be noted, elements not held by fixtures, such as second cable element 1860b and third cable element 1860c may sag or move away from where the associated indicia 1840 indicated the elements to be placed.

Because the display devices are able to move independently of where the fixtures are affixed to the mounting surface (either view a positioning system that moves display screens on an opposite side of a transparent screen 1270 or refocus where projectors display images/video on a projection surface), the placed elements may remain in place, while the system repurposes the display devices to display new portions of a schematic. For example, as shown in FIG. 18I, the second display 410b is moved to a new location to display a new fixture placement indica 1810d for assembling the third portion 1310c of the schematic with the elements already placed remaining in the location shown in FIG. 18H.

In FIG. 18J, the operator has installed a fixture 1830d where the fixture placement indica 1810d was indicated in FIG. 18H, and the display devices 410 may cease displaying the associated element indica.

In FIG. 18K, the operator has installed an element 1850e to join the cable elements 1860b-c, and has completed the assembly of the article of manufacture according to the schematic 1300 shown in FIG. 18A. When assembling a second or subsequent article of manufacture according to the same schematic, the system may omit presenting the fixture placement indicia 1810 under the assumption that the fixtures 1830 will remain attached to the assembly surface, and only element indicia 1840 may be displayed during assembly of subsequent articles of manufacture.

The present disclosure may also be understood with reference to the following numbered clauses:

Clause 1: A system, comprising: a first dynamic display device, having a first surface configured to display a first portion of a schematic; a second dynamic display device, having a second surface configured to display a second portion of the schematic; and a computing device, comprising a processor and a memory including instructions that when executed by the processor perform operations comprising: identifying a first physical position of the first dynamic display device in a physical environment; identifying a second physical position of the second dynamic display device in the physical environment; and selecting the first portion from the schematic based on sizes of the first dynamic display device and the second dynamic display device and a first correlation of the first physical position to a first schematic position in the schematic and a second correlation of the second physical position to a second schematic position in the schematic.

Clause 2: The system of any of clauses 1 or 3-11, further comprising: a fixture, comprising: a base; and an mounting hardware bonded on a first side to the base and on a second side, opposite to the first side, bonded to the first surface or the second surface, wherein the mounting hardware is selected from the group consisting of: viscoelastic strips; suction cups; magnets; and pegs configured for insertion into holes defined in the first surface or the second surface; wherein the sizes of the first dynamic display device and the second dynamic display device include a fixture width and a fixture length defining a space in which the fixture is mountable to the first surface or the second surface based on the mounting hardware used and a form factor of the base.

Clause 3: The system of any of clauses 1-2 or 4-11, wherein the operations further comprise: identifying a set of modular components for a fabrication system configurable for fabrication of an article of manufacture according to the schematic, the set of modular components including a first dynamic display device and a second dynamic display device; identifying available screen spaces and physical device sizes of the first dynamic display device and the second dynamic display device; dividing elements shown in the schematic to placements in a first portion for display on the first dynamic display device, a second portion for display on the second dynamic display device, and a third portion for non-display according to the available screen spaces and physical devices sizes and types of the elements shown in the schematic; and displaying the first portion of the schematic on the first dynamic display device and the second portion of the schematic on the second dynamic display device based on the placements, wherein the elements of the article of manufacture included in the third portion of the schematic that is not displayed on either the first dynamic display device or the second dynamic display device only include cables from the article of manufacture and a size of the third portion corresponds to a difference between the screen spaces and the physical device sizes of the first dynamic display device and the second dynamic display device.

Clause 4: The system of any of clauses 1-3 or 5-11, wherein the operations further comprise: identifying a first source node for a wire harness connected to a plurality of test devices from among a plurality of nodes in the wire harness based on a centrality of the first source node to other nodes of the plurality of nodes; testing a first set of signal pathways from the first source node to the other nodes of the plurality of nodes that are connected to the plurality of test devices; in response to detecting a fault in the first set of signal pathways from the first source node to the other nodes: identifying a first prospective fault location within the wire harness; identifying a second source node for the wire harness among a subset of the plurality of nodes that reported the fault; testing a second set of signal pathways from the second source node to the other nodes of a subset of the plurality of nodes; and updating the first prospective fault location based on the first set of signal pathways and the second set of signal pathways identified with the fault.

Clause 5: The system of any of clauses 1-4 or 6-11, wherein the first dynamic display device is connect to a first frame via a first armature connected to the first frame via a first rider, wherein the first rider provides movement for the first dynamic display device in a first direction defined by the first frame.

Clause 6: The system of any of clauses 1-5 or 7-11, further comprising a positioning system including a plurality of tracks secured to a pair of frames, wherein a first track of the plurality of tracks is associated with the first dynamic display device and permits movement of the first dynamic display device according to at least two degrees of freedom, wherein a second track of the plurality of tracks is associated with the second dynamic display device and permits movement of the second dynamic display device according to at least two degrees of freedom in a second plane different from a first plane in which the first track permits movement of the first dynamic display device.

Clause 7: The system of any of clauses 1-6 or 8-11, further comprising a transparent screen, wherein the first dynamic display device and the second dynamic display device are disposed on a first side of the transparent screen and display the schematic through the transparent screen to a second side of the transparent screen, opposite to the first side.

Clause 8: The system of any of clauses 1-7 or 9-11, further comprising a frame on which the first dynamic display device and the second dynamic display device are held, the frame including an interconnect port for a cable included in an article of manufacture indicated in the schematic configured to test transmission within the cable, wherein the interconnect port is selected from the group consisting of: an electrical connection when the cable includes an electrical wire; an optical connection when the cable includes a fiber optic strand; a hydraulic fluid connection when the cable includes a hydraulic hose; a flowing fluid connection when the cable includes a fluid delivery hose; and a pneumatic connection when the cable includes a pneumatic tube.

Clause 9: The system of any of clauses 1-8 or 10-11, wherein a third portion of the schematic is disposed between the first portion and the second portion, wherein the first dynamic display device is physically disposed relative to the second dynamic display device such that the third portion of the schematic corresponds to physical space between the first dynamic display device and the second dynamic display device.

Clause 10. The system of any of clauses 1-9 or 11, wherein the first portion and the second portion of the schematic display elements of the schematic at a 1:1 ratio between a schematic representation and a physical representation on the first dynamic display device and the second dynamic display device, wherein the first dynamic display device and the second dynamic display device are positioned such that a distance between the first dynamic display device and the second dynamic display device in which the third portion of the schematic is at least partially disposed is less than what a 1:1 ratio between the schematic representation and the physical representation would indicate the distance to be.

Clause 11. The system of any of clauses 1-10, wherein the first physical position includes a location of the first dynamic display device in the physical environment relative to a physical reference point that is matched to an electronic reference point in the schematic, and an orientation of the first dynamic display device with respect to an aspect ratio of the first dynamic display device.

Clause 12: A method for multi-display handing, comprising: retrieving a schematic of an article of manufacture; identifying a set of modular components for a fabrication system configurable for fabrication of the article of manufacture according to the schematic, the set of modular components including a first dynamic display device and a second dynamic display device; identifying available screen spaces and physical device sizes of the first dynamic display device and the second dynamic display device; dividing elements shown in the schematic to placements in a first portion for display on the first dynamic display device, a second portion for display on the second dynamic display device, and a third portion for non-display according to the available screen spaces and physical devices sizes and types of the elements shown in the schematic; and displaying the first portion of the schematic on the first dynamic display device and the second portion of the schematic on the second dynamic display device based on the placements, wherein the elements of the article of manufacture included in the third portion of the schematic that is not displayed on either the first dynamic display device or the second dynamic display device only include cables from the article of manufacture and a size of the third portion corresponds to a difference between the screen spaces and the physical device sizes of the first dynamic display device and the second dynamic display device.

Clause 13: The method of any of clauses 12 or 14-19, wherein the set of modular components include fixtures configured to selectively mount to a screen on which the schematic is displayed and to hold elements of the article of manufacture indicated in the schematic, wherein the available screen spaces is adjusted based on a size and a mounting hardware used by the fixtures.

Clause 14: The method of any of clauses 12-13 or 15-19, wherein the first dynamic display device has a different size, aspect ratio, or rotational orientation relative to the second dynamic display device.

Clause 15: The method of any of clauses 12-14 or 16-19, wherein the first portion includes a given element of an article of manufacture indicated in the schematic, wherein the second portion includes the given element of the article of manufacture indicated in the schematic, wherein the first dynamic display device is positioned to overlap the second dynamic display device when viewed in a first plane and to be offset from the second dynamic display device when viewed in a second plane.

Clause 16: The method of any of clauses 12-15 or 17-19, further comprising: dividing the elements shown in the schematic to placements in a third portion for display on the first dynamic display device, wherein the first dynamic display device displays the first portion when located at a first position in a frame of the fabrication system and displays the third portion when located at a second position in the frame of the fabrication system, wherein the fabrication system is configured to move the first dynamic display device from the first position to the second position in response to receiving a signal indicating that the elements of the article of manufacture in the first portion have been assembled.

Clause 17: The method of any of clauses 12-16 or 18-19, further comprising: selecting the first dynamic display device and the second dynamic display device from a plurality of available display devices that includes at least at the first dynamic display device, the second dynamic display device, and a third dynamic display device that is omitted from the set of modular components used for displaying the schematic based on the available screen spaces and physical device sizes of the first dynamic display device and the second dynamic display device and sizes and positions of the elements of the article of manufacture in the schematic.

Clause 18: The method of any of clauses 12-17 or 19, wherein a relative position of the first dynamic display device in the fabrication system is based on locations of connection ports on a frame of the fabrication system to which the article of manufacture, when fabricated according the first portion displayed on the first dynamic display device, are connected to for test of the article of manufacture.

Clause 19: The method of any of clauses 12-18, wherein an artificial intelligence (AI) module optimizes selection and placement of the set of modular components in the fabrication system for fabrication, test, and repair of wire harnesses.

Clause 20: A method for testing a wire harness, comprising: identifying a first source node for a wire harness connected to a plurality of test devices from among a plurality of nodes in the wire harness based on a centrality of the first source node to other nodes of the plurality of nodes; testing a first set of signal pathways from the first source node to the other nodes of the plurality of nodes that are connected to the plurality of test devices; in response to detecting a fault in the first set of signal pathways from the first source node to the other nodes: identifying a first prospective fault location within the wire harness; identifying a second source node for the wire harness among a subset of the plurality of nodes that reported the fault; testing a second set of signal pathways from the second source node to the other nodes of a subset of the plurality of nodes; and updating the first prospective fault location based on the first set of signal pathways and the second set of signal pathways identified with the fault.

Clause 21: The method of any of clauses 20 or 22-25, wherein testing the first set of signal pathways further comprises applying a transmission to the first source node, the transmission selected from the group consisting of: electrical signals; optical signals; hydraulic pressure waves; fluid flow volumes; and pneumatic pressure waves.

Clause 22: The method of any of clauses 20-21 or 23-25, further comprising, in response to identifying the first prospective fault location within the wire harness: changing a configuration of an element of the wire harness between the first source node and the first prospective fault location before testing a second set of signal pathways.

Clause 23: The method of any of clauses 20-22 or 24-25, further comprising, in response to identifying the first prospective fault location within the wire harness: replacing an element of the wire harness between the first source node and the first prospective fault location before testing a second set of signal pathways.

Clause 24: The method of any of clauses 20-23 or 25, further comprising: in response to detecting the fault in the first set of signal pathways from the first source node to the other nodes: positioning a dynamic display device behind the first prospective fault location within the wire harness relative to an operator; and displaying a portion of a schematic of the wire harness corresponding to the first prospective fault location.

Clause 25: The method of any of clauses 20-24, wherein the wire harness is received with an initially unknown configuration, the method further comprising: receiving a wire harness of an initially unknown configuration; connecting nodes of the wire harness to test devices; generating first signals between the test devices and identifying first receptions at the nodes to generate a first prospective harness schematic for the wire harness of the initially unknown configuration; comparing the first prospective harness schematic against known harness designs; and in response to the first prospective harness schematic not directly matching any of the known harness designs: identifying an error in the wire harness based on a use case of the wire harness and a partial match to a given one of the known harness designs; instructing a repair of the wire harness based on the error and the partial match; generating second signals between the test devices and identifying second receptions at the nodes to generate a second prospective harness schematic for the wire harness of the initially unknown configuration; comparing the second prospective harness schematic against the known harness designs; and in response to the second prospective harness schematic matching the given one of the known harness designs, passing test for the wire harness of the initially unknown configuration.

Clause 26: A method, comprising: receiving a wire harness of an initially unknown configuration; connecting nodes of the wire harness to test devices; generating first signals between the test devices and identifying first receptions at the nodes to generate a first prospective harness schematic for the wire harness of the initially unknown configuration; comparing the first prospective harness schematic against known harness designs; and in response to the first prospective harness schematic not directly matching any of the known harness designs: identifying an error in the wire harness based on a use case of the wire harness and a partial match to a given one of the known harness designs; instructing a repair of the wire harness based on the error and the partial match; generating second signals between the test devices and identifying second receptions at the nodes to generate a second prospective harness schematic for the wire harness of the initially unknown configuration; comparing the second prospective harness schematic against the known harness designs; and in response to the second prospective harness schematic matching the given one of the known harness designs, passing test for the wire harness of the initially unknown configuration.

Clause 27: The method of clause 26, wherein the first signals include transmission selected from the group consisting of: electrical signals; optical signals; hydraulic pressure waves; fluid flow volumes; and pneumatic pressure waves.

Clause 28: A method, comprising: retrieving a schematic of an article of manufacture; identifying a plurality of assembly surfaces to display the schematic according to a scaling ratio for displayed versions of elements of the article of manufacture relative to physical versions of the elements of the article of manufacture; dividing the schematic into a plurality of portions having at least a first portion including a first set of the elements of the article of manufacture, a second portion including a second set of the elements of the article of manufacture, and a remainder portion including segments of the schematic in which the first set and the second set are not included, wherein the first portion is at least partially discontinuous with the second portion, wherein a first size of the first portion and a second size of the second portion are based at least in part on: the scaling ratio; physical dimensions of the plurality of assembly surfaces display spaces within the physical dimensions of the plurality of assembly surfaces configured for display of portions of the schematic; and fixture spaces within the display spaces of the plurality of assembly surfaces configured to selectively mount fixtures thereto for assembly of the article of manufacture; displaying the first portion of the schematic on a first assembly surface of the plurality of assembly surfaces; and displaying the second portion of the schematic on a second assembly surface of the plurality of assembly surfaces, contemporaneously to displaying the first portion of the schematic on the first assembly surface.

Clause 29: The method of any of clause 28 or 30-36, wherein the first set of the elements includes at least one element included in the second set of the elements, wherein the first assembly surface partially overlaps the second assembly surface.

Clause 30: The method of any of clauses 28-29 or 31-36, wherein a gap distance between the first assembly surface and the second assembly surface includes a first margin of a first display device on which the first portion is displayed and a second margin of a second display device on which the second portion is displayed.

Clause 31: The method of any of clauses 28-30 or 32-36, wherein the first assembly surface is selected from the group consisting of: projection surfaces associated with projectors; computer monitors; televisions; touch screen devices; and a transparent screen disposed between a display device and a fabricator.

Clause 32: The method of any of clauses 28-31 or 33-36, wherein the remainder portion is disposed at least partially between the first portion and the second portion of the schematic, wherein the first portion and the second portion are displayed according to the scaling ratio, wherein a physical distance between the first assembly surface and the second assembly surface is less than a schematic distance between the first portion and the second portion.

Clause 33: The method of any of clauses 28-32 or 34-36, wherein the plurality of portions includes a third portion including a third set of the elements of the article of manufacture, wherein the first portion is displayed via a first display device and the second portion is displayed via a second display device, the method further comprising, after contemporaneously displaying the first portion and the second portion: adjusting the first display device used from a first location to a second location in an environment; and displaying the third portion of the schematic via the first display device.

Clause 34: The method of any of clauses 28-33 or 35-36, further comprising: before displaying the first portion of the schematic on the first assembly surface, displaying fixture placement indicia on the first assembly surface associated with fabrication of the article of manufacture according to the schematic; and removing display of the fixture placement indicia in response to receiving a command to proceed to displaying the first set of elements.

Clause 35: The method of any of clauses 28-34 or 36, wherein displaying the first portion of the schematic on the first assembly surface includes: displaying a first subset of the first set of the elements at a first time; and displaying a second subset of the first set of the elements at a second time that were not displayed at the first time, wherein display of the second subset replaces display of the first subset in response to receiving a command to proceed to displaying the second subset of the first set of elements.

Clause 36: The method of any of clauses 28-35, wherein displaying the first portion of the schematic on the first assembly surface includes at least one of: displaying notes or instructions associated with the first set of elements in fabricating the article of manufacture; and animating display of the first set of elements.

Clause 37: A system comprising: a first dynamic display device, having a first surface configured to display a first portion of a schematic; a second dynamic display device, having a second surface configured to display a second portion of the schematic; and a computing device, comprising a processor and a memory including instructions that when executed by the processor perform operations comprising: retrieving the schematic of the article of manufacture; identifying a set of modular components for a fabrication system configurable for fabrication of the article of manufacture according to the schematic, the set of modular components including the first dynamic display device and the second dynamic display device; identifying available screen spaces and physical device sizes of the first dynamic display device and the second dynamic display device; dividing elements shown in the schematic to placements in a first portion for display on the first dynamic display device, a second portion for display on the second dynamic display device, and a third portion for non-display according to the available screen spaces and physical devices sizes and types of the elements shown in the schematic; and displaying the first portion of the schematic on the first dynamic display device and the second portion of the schematic on the second dynamic display device based on the placements, wherein the elements of the article of manufacture included in the third portion of the schematic that is not displayed on either the first dynamic display device or the second dynamic display device only include cables from the article of manufacture and a size of the third portion corresponds to a difference between the screen spaces and the physical device sizes of the first dynamic display device and the second dynamic display device.

Clause 38: A system comprising: a processor; and a memory including instructions that when executed by the processor perform operations comprising: identifying a first source node for a wire harness connected to a plurality of test devices from among a plurality of nodes in the wire harness based on a centrality of the first source node to other nodes of the plurality of nodes; testing a first set of signal pathways from the first source node to the other nodes of the plurality of nodes that are connected to the plurality of test devices; in response to detecting a fault in the first set of signal pathways from the first source node to the other nodes: identifying a first prospective fault location within the wire harness; identifying a second source node for the wire harness among a subset of the plurality of nodes that reported the fault; testing a second set of signal pathways from the second source node to the other nodes of a subset of the plurality of nodes; and updating the first prospective fault location based on the first set of signal pathways and the second set of signal pathways identified with the fault.

Clause 39: A system configured to perform any of the methods of clauses 1-38.

Clause 40: A method as performed by any of the systems of clauses 1-38.

Certain terms are used throughout the description and claims to refer to particular features or components. As one skilled in the art will appreciate, different persons may refer to the same feature or component by different names. This document does not intend to distinguish between components or features that differ in name but not function.

As used herein, the term “optimize” and variations thereof, is used in a sense understood by data scientists to refer to actions taken for continual improvement of a system relative to a goal. An optimized value will be understood to represent “near-best” value for a given reward framework, which may oscillate around a local maximum or a global maximum for a “best” value or set of values, which may change as the goal changes or as input conditions change. Accordingly, an optimal solution for a first goal at a given time may be suboptimal for a second goal at that time or suboptimal for the first goal at a later time.

As used in the present disclosure, the term “determining” encompasses a variety of actions that may include calculating, computing, processing, deriving, investigating, looking up (e.g., via a table, database, or other data structure), ascertaining, receiving (e.g., receiving information), accessing (e.g., accessing data in a memory), retrieving, resolving, selecting, choosing, establishing, and the like.

As used herein, “about,” “approximately” and “substantially” are understood to refer to numbers in a range of the referenced number, for example the range of −10% to +10% of the referenced number, preferably −5% to +5% of the referenced number, more preferably −1% to +1% of the referenced number, most preferably −0.1% to +0.1% of the referenced number.

Furthermore, all numerical ranges herein should be understood to include all integers, whole numbers, or fractions, within the range. Moreover, these numerical ranges should be construed as providing support for a claim directed to any number or subset of numbers in that range. For example, a disclosure of from 1 to 10 should be construed as supporting a range of from 1 to 8, from 3 to 7, from 1 to 9, from 3.6 to 4.6, from 3.5 to 9.9, and so forth.

As used in the present disclosure, a phrase referring to “at least one of” a list of items refers to any set of those items, including sets with a single member, and every potential combination thereof. For example, when referencing “at least one of A, B, or C” or “at least one of A, B, and C”, the phrase is intended to cover the sets of: A, B, C, A-B, B-C, A-C, and A-B-C, where the sets may include one or multiple instances of a given member (e.g., A-A, A-A-A, A-A-B, A-A-B-B-C-C-C, etc.) and any ordering thereof. For avoidance of doubt, the phrase “at least one of A, B, and C” shall not be interpreted to mean “at least one of A, at least one of B, and at least one of C”.

Without further elaboration, it is believed that one skilled in the art can use the preceding description to use the claimed inventions to their fullest extent. The examples and aspects disclosed herein are to be construed as merely illustrative and not a limitation of the scope of the present disclosure in any way. It will be apparent to those having skill in the art that changes may be made to the details of the above-described examples without departing from the underlying principles discussed. In other words, various modifications and improvements of the examples specifically disclosed in the description above are within the scope of the appended claims. For instance, any suitable combination of features of the various examples described is contemplated.

Within the claims, reference to an element in the singular is not intended to mean “one and only one” unless specifically stated as such, but rather as “one or more” or “at least one”. Unless specifically stated otherwise, the term “some” refers to one or more. No claim element is to be construed under the provision of 35 U.S.C. § 112 (f) unless the element is expressly recited using the phrase “means for” or “step for”. All structural and functional equivalents to the elements of the various embodiments described in the present disclosure that are known or come later to be known to those of ordinary skill in the relevant art are expressly incorporated herein by reference and are intended to be encompassed by the claims. Moreover, nothing disclosed in the present disclosure is intended to be dedicated to the public regardless of whether such disclosure is explicitly recited in the claims.

1. A system, comprising:
a first dynamic display device, having a first surface configured to display a first portion of a schematic of a wire harness;
a second dynamic display device, having a second surface configured to display a second portion of the schematic; and
a computing device, comprising a processor and a memory including instructions that when executed by the processor perform operations comprising:
identifying a first physical position of the first dynamic display device in a physical environment;
identifying a second physical position of the second dynamic display device in the physical environment; and
selecting the first portion from the schematic based on sizes of the first dynamic display device and the second dynamic display device and a first correlation of the first physical position to a first schematic position in the schematic and a second correlation of the second physical position to a second schematic position in the schematic.

2. The system of claim 1, further comprising:
a fixture, comprising:
a base; and
an mounting hardware bonded on a first side to the base and on a second side, opposite to the first side, bonded to the first surface or the second surface, wherein the mounting hardware is selected from the group consisting of:
viscoelastic strips;
suction cups;
magnets; and
pegs configured for insertion into holes defined in the first surface or the second surface;
wherein the sizes of the first dynamic display device and the second dynamic display device include a fixture width and a fixture length defining a space in which the fixture is mountable to the first surface or the second surface based on the mounting hardware used and a form factor of the base.

3. The system of claim 1, wherein the operations further comprise:
identifying a set of modular components for a fabrication system configurable for fabrication of the wire harness according to the schematic, the set of modular components including a first dynamic display device and a second dynamic display device;
identifying available screen spaces and physical device sizes of the first dynamic display device and the second dynamic display device;
dividing elements shown in the schematic to placements in a first portion for display on the first dynamic display device, a second portion for display on the second dynamic display device, and a third portion for non-display according to the available screen spaces and physical devices sizes and types of the elements shown in the schematic; and
displaying the first portion of the schematic on the first dynamic display device and the second portion of the schematic on the second dynamic display device based on the placements, wherein the elements of the article of manufacture included in the third portion of the schematic that is not displayed on either the first dynamic display device or the second dynamic display device only include cables from the article of manufacture and a size of the third portion corresponds to a difference between the screen spaces and the physical device sizes of the first dynamic display device and the second dynamic display device.

4. The system of claim 1, wherein the operations further comprise: identifying a first source node for a wire harness connected to a plurality of test devices from among a plurality of nodes in the wire harness based on a centrality of the first source node to other nodes of the plurality of nodes;
testing a first set of signal pathways from the first source node to the other nodes of the plurality of nodes that are connected to the plurality of test devices;
in response to detecting a fault in the first set of signal pathways from the first source node to the other nodes:
identifying a first prospective fault location within the wire harness;
identifying a second source node for the wire harness among a subset of the plurality of nodes that reported the fault;
testing a second set of signal pathways from the second source node to the other nodes of a subset of the plurality of nodes; and
updating the first prospective fault location based on the first set of signal pathways and the second set of signal pathways identified with the fault.

5. The system of claim 1, wherein the first dynamic display device is connect to a first frame via a first armature connected to the first frame via a first rider, wherein the first rider provides movement for the first dynamic display device in a first direction defined by the first frame.

6. The system of claim 1, further comprising a positioning system including a plurality of tracks secured to a pair of frames, wherein a first track of the plurality of tracks is associated with the first dynamic display device and permits movement of the first dynamic display device according to at least two degrees of freedom, wherein a second track of the plurality of tracks is associated with the second dynamic display device and permits movement of the second dynamic display device according to at least two degrees of freedom in a second plane different from a first plane in which the first track permits movement of the first dynamic display device.

7. The system of claim 1, further comprising a transparent screen, wherein the first dynamic display device and the second dynamic display device are disposed on a first side of the transparent screen and display the schematic through the transparent screen to a second side of the transparent screen, opposite to the first side.

8. The system of claim 1, further comprising a frame on which the first dynamic display device and the second dynamic display device are held, the frame including an interconnect port for a cable included in an article of manufacture indicated in the schematic configured to test transmission within the cable, wherein the interconnect port is selected from the group consisting of:
an electrical connection when the cable includes an electrical wire;
an optical connection when the cable includes a fiber optic strand;
a hydraulic fluid connection when the cable includes a hydraulic hose;
a flowing fluid connection when the cable includes a fluid delivery hose; and
a pneumatic connection when the cable includes a pneumatic tube.

9. The system of claim 1, wherein a third portion of the schematic is disposed between the first portion and the second portion, wherein the first dynamic display device is physically disposed relative to the second dynamic display device such that the third portion of the schematic corresponds to physical space between the first dynamic display device and the second dynamic display device.

10. The system of claim 9, wherein the first portion and the second portion of the schematic display elements of the schematic at a 1:1 ratio between a schematic representation and a physical representation on the first dynamic display device and the second dynamic display device, wherein the first dynamic display device and the second dynamic display device are positioned such that a distance between the first dynamic display device and the second dynamic display device in which the third portion of the schematic is at least partially disposed is less than what a 1:1 ratio between the schematic representation and the physical representation would indicate the distance to be.

11. The system of claim 1, wherein the first physical position includes a location of the first dynamic display device in the physical environment relative to a physical reference point that is matched to an electronic reference point in the schematic, and an orientation of the first dynamic display device with respect to an aspect ratio of the first dynamic display device.

12-27. (canceled)

28. A method, comprising:
retrieving a schematic of a wire harness;
identifying a plurality of assembly surfaces to display the schematic according to a scaling ratio for displayed versions of elements of the wire harness relative to physical versions of the elements of the wire harness;
dividing the schematic into a plurality of portions having at least a first portion including a first set of the elements of the wire harness, a second portion including a second set of the elements of the wire harness, and a remainder portion including segments of the schematic in which the first set and the second set are not included, wherein the first portion is at least partially discontinuous with the second portion, wherein a first size of the first portion and a second size of the second portion are based at least in part on:
the scaling ratio;
physical dimensions of the plurality of assembly surfaces
display spaces within the physical dimensions of the plurality of assembly surfaces configured for display of portions of the schematic; and
fixture spaces within the display spaces of the plurality of assembly surfaces configured to selectively mount fixtures thereto for assembly of the wire harness;
displaying the first portion of the schematic on a first assembly surface of the plurality of assembly surfaces; and
displaying the second portion of the schematic on a second assembly surface of the plurality of assembly surfaces, contemporaneously to displaying the first portion of the schematic on the first assembly surface.

29. The method of claim 28, wherein the first set of the elements includes at least one element included in the second set of the elements, wherein the first assembly surface partially overlaps the second assembly surface.

30. The method of claim 28, wherein a gap distance between the first assembly surface and the second assembly surface includes a first margin of a first display device on which the first portion is displayed and a second margin of a second display device on which the second portion is displayed.

31. The method of claim 28, wherein the first assembly surface is selected from the group consisting of:
projection surfaces associated with projectors;
computer monitors;
televisions;
touch screen devices; and
a transparent screen disposed between a display device and a fabricator.

32. The method of claim 28, wherein the remainder portion is disposed at least partially between the first portion and the second portion of the schematic, wherein the first portion and the second portion are displayed according to the scaling ratio, wherein a physical distance between the first assembly surface and the second assembly surface is less than a schematic distance between the first portion and the second portion.

33. The method of claim 28, wherein the plurality of portions includes a third portion including a third set of the elements of the wire harness, wherein the first portion is displayed via a first display device and the second portion is displayed via a second display device, the method further comprising, after contemporaneously displaying the first portion and the second portion:
adjusting the first display device used from a first location to a second location in an environment; and
displaying the third portion of the schematic via the first display device.

34. The method of claim 28, further comprising:
before displaying the first portion of the schematic on the first assembly surface, displaying fixture placement indicia on the first assembly surface associated with fabrication of the wire harness according to the schematic; and
removing display of the fixture placement indicia in response to receiving a command to proceed to displaying the first set of elements.

35. The method of claim 28, wherein displaying the first portion of the schematic on the first assembly surface includes:
displaying a first subset of the first set of the elements at a first time; and
displaying a second subset of the first set of the elements at a second time that were not displayed at the first time, wherein display of the second subset replaces display of the first subset in response to receiving a command to proceed to displaying the second subset of the first set of elements.

36. The method of claim 28, wherein displaying the first portion of the schematic on the first assembly surface includes at least one of:
displaying notes or instructions associated with the first set of elements in fabricating the wire harness; and
animating display of the first set of elements.

37-38. (canceled)
